(19) United States
(12) Patent Application Publication
(10) Pub. No.: US 2012/0312343 A1
(43) Pub. Date: Dec. 13, 2012

(54) NANOSTRUCTURED MATERIAL BASED THERMOELECTRIC GENERATORS AND METHODS OF GENERATING POWER

(75) Inventors: Tom VanVechten, Warner, NH (US); David S. Lashmore, Lebanon, NH (US); Diana Lewis, Northfield, NH (US)

(73) Assignee: Nanocomp Technologies, Inc., Concord, NH (US)

(21) Appl. No.: 13/445,576

(22) Filed: Apr. 12, 2012

Related U.S. Application Data
(60) Provisional application No. 61/474,515, filed on Apr. 12, 2011.

(51) Int. Cl. H01L 35/32; H01L 35/28; H01L 35/30

(52) U.S. Cl. 136/201; 136/205; 136/208

(57) ABSTRACT

Systems for producing electrical energy from heat are disclosed. The system may include a carbon-nanotube based pathway along which heat from a source can be directed. An array of thermoelectric elements for generating electrical energy may be situated about a surface of the pathway to enhance the generation of electrical energy. A carbon nanotube-based, heat-dissipating member may be in thermal communication with the array of thermoelectric elements and operative to create a heat differential between the thermoelectric elements and the pathway by dissipating heat from the thermoelectric elements. The heat differential may allow the thermoelectric elements to generate the electrical energy. Methods for producing electrical energy are also disclosed.

### RELATED U.S. APPLICATIONS

This application claims priority to, and the benefit of, U.S. Provisional Application No. 61/474,515 filed Apr. 12, 2011, which is incorporated herein by reference in its entirety.

### TECHNICAL FIELD

The present invention relates to power generators, and more particularly, to thermoelectric power generators using nanostructured materials.

### BACKGROUND ART

Thermoelectric generators are usually made from semiconductor “n” and “p” type elements arranged in series, and can be attached on one side to a hot plate or heat source, and on the other side to a cold plate or heat sink. The efficiency of these generators includes fundamentally the Carnot efficiency and secondarily the device efficiency, with overall energy conversion values of less than about 10% and usually less than about 5%.

These devices typically rely on semiconductor materials having, among other things, a relatively high Seebeck coefficient, S, a change in voltage with temperature, a high electrical conductivity, σ, and a low thermal conductivity, λ.

The figure of merit, therefore, can be expressed in accordance with Equation (1):

ZT=S²*σ*ΔT/λ (1)

so that materials with a high thermal conductivity λ tend to behave poorly as thermoelectric generators, because they can leak away thermal energy that otherwise can contribute to power generation.

In some instances, the figure of merit expressing the electrical power produced divided by the thermal power to the hot junction can be expressed in Equation (2):

ZT=(Sp−Sn)2/(√ρpκp+√ρnκn)2(for a junction) (2)

where

S: Seebeck coefficient

ρ: Resistivity

κ: Thermal conductivity

Similarly, the voltage output for a thermoelectric effect can be calculated, given the Seebeck coefficient, the number of elements present, and the temperature differential between the hot and the cold junction according to Equation (3):

V=S*n*ΔT (3)

Where V is the output voltage (in volts), S is the Seebeck coefficient (in V/K), n is the number of elements in the series, and ΔT is the temperature difference between the hot and cold sides of the device.

It should be noted that the weight of these materials, in many instances, typically does not come into consideration. However, for many practical considerations, weight may be important. For example, Bi₂Te₃, an often used material in the manufacturing of thermoelectric devices, because its ZT value is about 1, has a density of about 7.4 g/cc to about 7.7 g/cc. As such, devices made of this high performance material can be relatively heavy.

Moreover, many of the applications for which the use of a thermoelectric generator can be contemplated requires a thermoelectric device that has a substantially high specific power. As an example, for single junction solar cell based arrays, a specific power of from about 25 W/kg to about 100 W/kg needs to be achieved. In addition, applications using, for instance, multi-junction GaAs arrays, a specific power of from about 200 W/kg to about 1000 W/kg may be needed.

However, thermoelectric devices or systems that utilize Bi₂Te₃, SiGe alloys, or other similar materials can only generate a specific power at a level of from about 1-5 W/kg. Furthermore, in many of the contemplated applications, the temperatures to which the thermoelectric devices can be exposed can be substantially high. Unfortunately, Bi₂Te₃, SiGe alloys, or other similar materials used in presently available thermoelectric devices or systems tend to melt as the temperature approaches about 400° C.

In some instances, photovoltaic energy harvesters e.g., photovoltaic cells, may convert, for instance, sunlight directly into electricity via collisions of photons with electrons in wafers of amorphous or microcrystalline silicon. Similarly, thermoelectric energy harvesters utilize waste heat to create a temperature difference which induces a current in a thermoelectric material such as bismuth telluride.

It would be desirable to provide thermoelectric devices that can be exposed to heat radiation and then generate a current due to the temperature differential created, that are efficient, yet lightweight, that can operate at substantially high temperature, and that can generate the necessary voltage to permit useful applications.

### SUMMARY OF THE INVENTION

Thermoelectric devices and methods are disclosed. The thermoelectric devices are capable of being used as a power source, or a voltage source, or a current source. In some instances, the thermoelectric device may also be a power generator. In some embodiments, the thermoelectric devices can convert waste heat to electrical energy.

In an embodiment, a thermoelectric system includes a carbon nanotube-based pathway along which heat from a source can be directed, an array of thermoelectric elements for generating electrical energy situated about a surface of the pathway to enhance the generation of electrical energy, and a carbon nanotube-based dissipating member coupled to the array of thermoelectric elements and operative to create a heat differential between the thermoelectric elements and the pathway by dissipating heat from the thermoelectric elements, so as to allow the thermoelectric elements to generate the electrical energy.

In an embodiment, the pathway may be a pipe or hose through which a heated fluid can flow. The pipe or hose can includes extensions projecting from a surface of the pipe into the flow of heated fluid to enhance the transfer of heat to the thermoelectric elements. The pathway can include thermally conductive, nanotube-based material to reduce the weight of the pathway while allowing heat transfer.

Each thermoelectric element in the array can include a carbon nanotube-based material that can convert heat to electrical energy. In an embodiment, the thermoelectric elements can be formed from a sheet of thermoelectric material, arranged to increase the mass of thermoelectric material in thermoelectric element. In some embodiments, the sheet can be rolled into a cylinder.

The thermoelectric elements may be in thermal communication with the pathway and the dissipating member, so that a heat differential can be formed across the thermoelectric elements to allow them to generate electrical energy. To enhance generation of electrical energy the thermoelectric elements can arranged in an ordered pattern to enhance the flow of heat through the thermoelectric elements.

In an embodiment, the dissipating member can be positioned circumferentially about the array of thermoelectric elements, so that the heat can be transferred radially from the pathway, through the thermoelectric elements, to the heat conductive member. The dissipating member can include a nanotube-based material to reduce the weight of the dissipating member while enhancing heat dissipation.

In another embodiment, a method of generating electrical energy includes transferring heat from a pathway into an array of thermoelectric elements. The thermoelectric elements may be arranged in a pattern about a pathway to enhance generation of electrical energy. A dissipating member, in thermal communication with the thermoelectric elements, may be used to dissipate the heat from the thermoelectric elements, so as to create a heat differential between the thermoelectric elements and the pathway. The thermoelectric elements, in the presence of the heat differential, may then generate the electrical energy.

### BRIEF DESCRIPTION OF DRAWINGS

FIG. 1 illustrates a Chemical Vapor Deposition system for fabricating a continuous sheet of nanotubes, in accordance with one embodiment of the present invention.

FIG. 2 illustrate a illustrate a Chemical Vapor Deposition system for fabricating a yarn made from nanotubes, in accordance with one embodiment of the present invention.

FIG. 3 illustrates the relationship between power conversion efficiency as a function of ZT.

FIG. 4 illustrates the Seebeck coefficient for individual nanotubes as a function of temperature.

FIG. 5 illustrates the Seebeck coefficient as a function of temperature for single-wall nanotube sheets.

FIG. 6 illustrates the power output from a thermoelectric device made with single-wall nanotube sheets as a function of temperature.

FIG. 7 illustrates linear array with copper plated onto single-wall nanotube sheet for use as a component of a thermoelectric device of the present invention.

FIGS. 8A-B illustrates the linear array in FIG. 7 wrapped up to provide a core of a thermoelectric device.

FIG. 9 illustrates a pocket solar collector with a thermoelectric device of the present invention.

FIG. 10 illustrates another solar collector with another configuration of a thermoelectric device, in accordance with an embodiment of the present invention.

FIGS. 11A-D illustrate a multi-element thermoelectric array for use as a thermoelectric device.

FIGS. 12A-B illustrate data from a thermoelectric device having a 5 element array and from thermoelectric device having a 30 element array.

FIGS. 13A-B illustrate a thermoelectric device having an alternating array core for energy harvesting, in accordance with an embodiment of the present invention.

FIG. 14 illustrates a thermoelectric core contained inside the thermoelectric device shown in FIGS. 13A-B.

FIG. 15 illustrates a perspective view of a thermoelectric device in accordance with one embodiment of the present invention.

FIG. 16 illustrates a top view of a continuous strip of carbon nanotubes used connection with a thermoelectric device in accordance with an embodiment of the present invention.

FIG. 17 illustrates the reflectance spectrum of solar energy at varying angles of incidence for multi-walled carbon nanotube material used in accordance with an embodiment of the present invention.

FIGS. 18-22 illustrate steps for manufacturing a thermoelectric device in accordance with an embodiment of the present invention.

FIG. 23 illustrates a cross sectional view of a thermoelectric device produced in accordance with an embodiment of the present invention.

FIG. 24 illustrates a CAD drawing of a thermoelectric device without a filler material according to one embodiment of the present invention.

FIG. 25 illustrates a CAD drawing of a thermoelectric device with a filler material according to one embodiment of the present invention.

FIG. 26 illustrates a CAD drawing of a thermoelectric device according to one embodiment of the present invention.

FIG. 27 illustrates a pathway and heat source.

FIG. 28 illustrates a thermoelectric element according to one embodiment of the present invention.

FIG. 29 illustrates a thermoelectric device according to one embodiment of the present invention.

### DESCRIPTION OF SPECIFIC EMBODIMENTS

Carbon nanotubes, such as those manufactured in accordance with an embodiment of the present invention, can exhibit a significant Seebeck effect. In particular, carbon nanotubes may exhibit a Seebeck coefficient that may be substantially linear with temperatures, for instance, from ambient to at least about 600° C. Moreover, the Seebeck coefficient for a structure made with substantially aligned carbon nanotubes can be measurably higher.

Furthermore, the carbon nanotubes of the present invention can have lower density than traditional materials used in making thermoelectric generators. As such, significant weight saving can be achieved by replacing the relatively heavy traditional materials with the lighter carbon nanotubes of the present invention. Due to their relatively lower density, relatively higher Seebeck effect, and relatively lower thermal conductivity, carbon nanotubes can be designed to achieve relatively high specific power.

Thermoelectric devices or generators of the present invention may be manufactured using, in one embodiment, at least one sheet or one yarn made from single, dual, or multiwall carbon nanotubes. In one embodiment, the sheet or yarn may be doped with p-type or n-type dopants, and subsequently coupled to a conductive material, such as copper or nickel. These affixed elements (i.e., doped sheet or yarn, and conductive material) may, thereafter, be arranged or assembled in various configurations to provide the thermoelectric devices or generators of the present invention. It should be appreciated that the flexibility and low density of carbon nanotubes, and thus the sheet or yarn, permit geometries that would not otherwise be possible with traditional semiconductor materials.

### Systems for Fabricating Nanotubes

Nanotubes for use in connection with the present invention may be fabricated using a variety of approaches. Presently, there exist multiple processes and variations thereof for growing nanotubes. These include: (1) Chemical Vapor Deposition (CVD), a common process that can occur at near ambient or at high pressures, and at temperatures above about 400° C., (2) Arc Discharge, a high temperature process that can give rise to tubes having a high degree of perfection, (3) Laser ablation, and (4) HIPCO.

The present invention, in one embodiment, employs a CVD process or similar gas phase pyrolysis procedures known in the industry to generate the appropriate nanostructures, including carbon nanotubes. Growth temperatures for a CVD process can be comparatively low ranging, for instance, from about 400° C. to about 1350° C. Carbon nanotubes, both single-walled (SWCNT) or multi-walled (MWCNT), may be grown, in an embodiment of the present invention, by exposing nanoscaled catalyst particles in the presence of reagent carbon-containing gases (i.e., gaseous carbon source). In particular, the nanoscaled catalyst particles may be introduced into the reagent carbon-containing gases, either by addition of existing particles or by in situ synthesis of the particles from a metal-organic precursor, or even non-metallic catalysts. Although both SWCNT and MWCNT may be grown, in certain instances, SWCNT may be selected due to their relatively higher growth rate and tendency to form rope-like structures. These rope-like structures can offer a number of advantages, including handling, lower thermal conductivity which can be a desirable feature for thermoelectric devices, good electronic conductivity, and high strength.

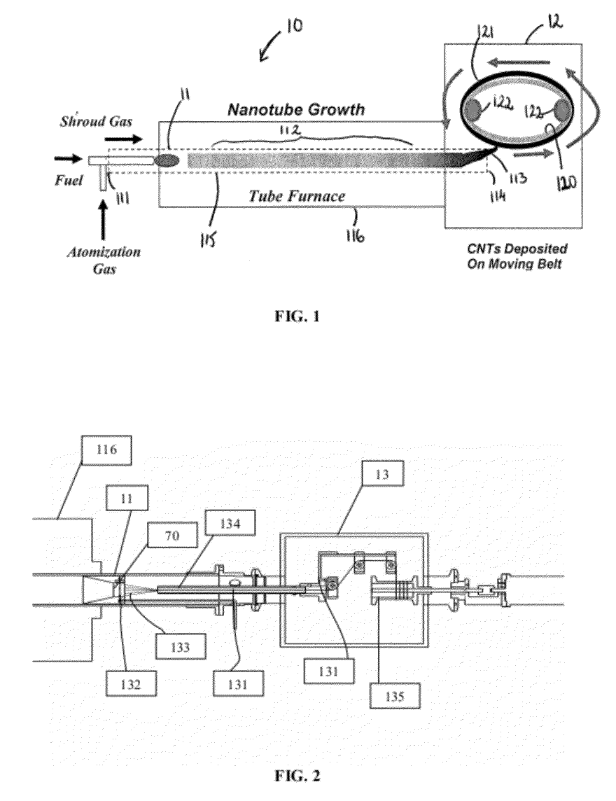

With reference now to FIG. 1, there is illustrated a system 10, similar to that disclosed in U.S. Pat. No. 7,993,620 filed Jul. 17, 2006 (incorporated herein by reference), for use in the fabrication of nanotubes. System 10, in an embodiment, may include a synthesis chamber 11. The synthesis chamber 11, in general, includes an entrance end 111, into which reaction gases (i.e., gaseous carbon source) may be supplied, a hot zone 112, where synthesis of nanotubes 113 may occur, and an exit end 114 from which the products of the reaction, namely a cloud of nanotubes and exhaust gases, may exit and be collected. The synthesis chamber 11, in an embodiment, may include a quartz tube, a ceramic tube or a FeCrAl tube 115 extending through a furnace 116. The nanotubes generated by system 10, in one embodiment, may be individual single-walled nanotubes, bundles of such nanotubes, and/or intermingled or intertwined single-walled nanotubes, all of which may be referred to hereinafter as “non-woven.”

System 10, in one embodiment of the present invention, may also include a housing 12 designed to be substantially fluid (e.g., gas, air, etc.) tight, so as to minimize the release of potentially hazardous airborne particulates from within the synthesis chamber 11 into the environment. The housing 12 may also act to prevent oxygen from entering into the system 10 and reaching the synthesis chamber 11. In particular, the presence of oxygen within the synthesis chamber 11 can affect the integrity and can compromise the production of the nanotubes 113.

System 10 may also include a moving belt 120, positioned within housing 12, designed for collecting synthesized nanotubes 113 generated from within synthesis chamber 11 of system 10. In particular, belt 120 may be used to permit nanotubes collected thereon to subsequently form a substantially continuous extensible structure 121, for instance, a CNT sheet. Such a CNT sheet may be generated from substantially non-aligned, non-woven nanotubes 113, with sufficient structural integrity to be handled as a sheet. Belt 120, in an embodiment, can be designed to translate back and forth in a direction substantially perpendicular to the flow of gas from the exit end 114, so as to increase the width of the CNT sheet 121 being collected on belt 120.

In an embodiment, after a first layer of nanotubes is collected onto belt 120, belt 120 may continue to turn so that additional non-woven nanotubes 113 can bond to sheet 121. As these additional nanotubes 113 bond and attach to sheet 121, they may produce additional layers so as to form a layered sheet 121. The number of layers in sheet 121 may be determined by how many rotations are made by belt 120 as the nanotubes 113 are deposited onto belt 120.

To collect the fabricated nanotubes 113, belt 120 may be positioned adjacent the exit end 114 of the synthesis chamber 11 to permit the nanotubes to be deposited on to belt 120. In one embodiment, belt 120 may be positioned substantially parallel to the flow of gas from the exit end 114, as illustrated in FIG. 1. Alternatively, belt 120 may be positioned substantially perpendicular to the flow of gas from the exit end 114 and may be porous in nature to allow the flow of gas carrying the nanomaterials to pass through the belt. In one embodiment, belt 120 can be designed to translate from side to side in a direction substantially perpendicular to the flow of gas from the exit end 114, so as to generate a sheet that is substantially wider than the exit end 114. Belt 120 may also be designed as a continuous loop, similar to a conventional conveyor belt, such that belt 120 can continuously rotate about an axis, whereby multiple substantially distinct layers of CNT can be deposited on belt 120 to form a sheet 121. To that end, belt 120, in an embodiment, may be looped about opposing rotating elements 122 and may be driven by a mechanical device, such as an electric motor. Alternatively, belt 120 may be a rigid cylinder, such as a drum. In one embodiment, the motor device may be controlled through the use of a control system, such as a computer or microprocessor, so that tension and velocity can be optimized.

To disengage the CNT sheet 121 of intermingled non-woven nanomaterials from belt 120 for subsequent removal from housing 12, a blade (not shown) may be provided adjacent the roller with its edge against surface of belt 120. In this manner, as CNT sheet 121 is rotated on belt 120 past the roller, the blade may act to lift the CNT sheet 121 from surface of belt 120. In an alternate embodiment, a blade does not have to be in use to remove the CNT sheet 121. Rather, removal of the CNT sheet may be by hand or by other known methods in the art.

Additionally, a spool (not shown) may be provided downstream of blade, so that the disengaged CNT sheet 121 may subsequently be directed thereonto and wound about the spool for harvesting. As the CNT sheet 121 is wound about the spool, a plurality of layers of CNT sheet 121 may be formed. Of course, other mechanisms may be used, so long as the CNT sheet 121 can be collected for removal from the housing 12 thereafter. The spool, like belt 120, may be driven, in an embodiment, by a mechanical drive, such as an electric motor, so that its axis of rotation may be substantially transverse to the direction of movement of the CNT sheet 121.

In order to minimize bonding of the CNT sheet 121 to itself as it is being wound about the spool, a separation material may be applied onto one side of the CNT sheet 121 prior to the sheet being wound about the spool. The separation material for use in connection with the present invention may be one of various commercially available metal sheets or polymers that can be supplied in a continuous roll. To that end, the separation material may be pulled along with the CNT sheet 121 onto the spool as sheet is being wound about the spool. It should be noted that the polymer comprising the separation material may be provided in a sheet, liquid, or any other form, so long as it can be applied to one side of CNT sheet 121. Moreover, since the intermingled nanotubes within the CNT sheet 121 may contain catalytic nanoparticles of a ferromagnetic material, such as Fe, Co, Ni, etc., the separation material, in one embodiment, may be a non-magnetic material, e.g., conducting or otherwise, so as to prevent the CNT sheet from sticking strongly to the separation material. In an alternate embodiment, a separation material may not be necessary.

After the CNT sheet 121 is generated, it may be left as a CNT sheet or it may be cut into smaller segments, such as strips. In an embodiment, a laser may be used to cut the CNT sheet 121 into strips as the belt 120 or drum rotates and/or simultaneously translates. The laser beam may, in an embodiment, be situated adjacent the housing 12 such that the laser may be directed at the CNT sheet 121 as it exits the housing 12. A computer or program may be employed to control the operation of the laser beam and also the cutting of the strip. In an alternative embodiment, any mechanical means or other means known in the art may be used to cut the CNT sheet 121 into strips.

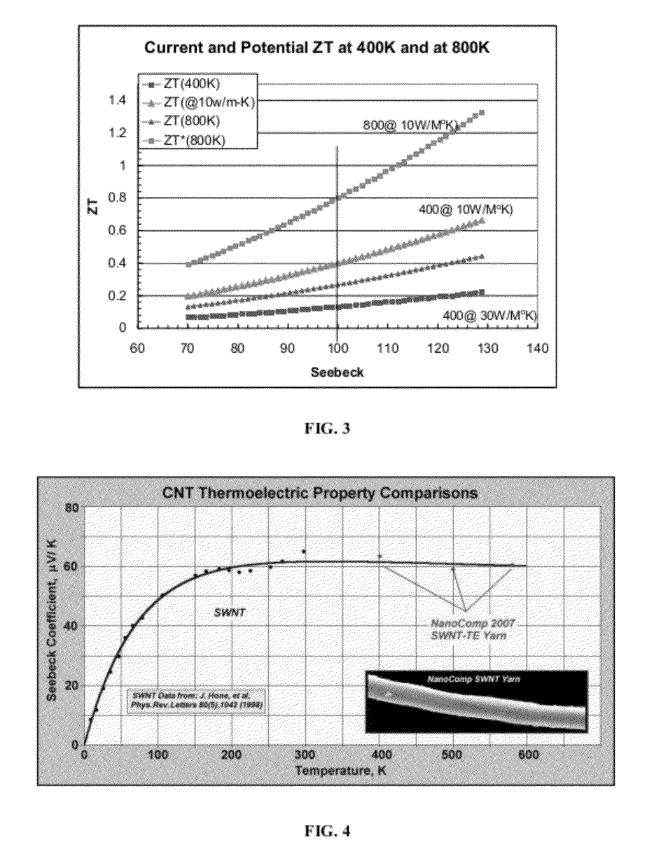

In an alternate embodiment, as illustrated in FIG. 2, instead of a non-woven sheet, the fabricated single-walled nanotubes 113 may be collected from synthesis chamber 11, and a yarn 131 may thereafter be formed. Specifically, as the nanotubes 113 emerge from the synthesis chamber 11, they may be collected into a bundle 132, fed into intake end 133 of a spindle 134, and subsequently spun or twisted into yarn 131 therewithin. It should be noted that a continual twist to the yarn 131 can build up sufficient angular stress to cause rotation near a point where new nanotubes 113 arrive at the spindle 134 to further the yarn formation process. Moreover, a continual tension may be applied to the yarn 131 or its advancement into collection chamber 13 may be permitted at a controlled rate, so as to allow its uptake circumferentially about a spool 135.

Typically, the formation of the yarn 131 results from a bundling of nanotubes 113 that may subsequently be tightly spun into a twisting yarn. Alternatively, a main twist of the yarn 131 may be anchored at some point within system 10 and the collected nanotubes 113 may be wound on to the twisting yarn 131. Both of these growth modes can be implemented in connection with the present invention.

### Nanotubes

The strength of the individual carbon nanotubes generated in connection with the present invention may be about 30 GPa or more. Strength, as should be noted, is sensitive to defects. However, the elastic modulus of the carbon nanotubes fabricated in the present invention may not be sensitive to defects and can vary from about 1 to about 1.2 TPa. Moreover, the strain to failure of these nanotubes, which generally can be a structure sensitive parameter, may range from a about 10% to a maximum of about 25% in the present invention.

The nanotubes of the present invention can also be provided with relatively small diameter. In an embodiment of the present invention, the nanotubes fabricated in the present invention can be provided with a diameter in a range of from less than 1 nm to about 10 nm.

The carbon nanotubes of the present invention can further demonstrate ballistic conduction as a fundamental means of conductivity. Thus, materials made from nanotubes of the present invention can represent a significant advance over copper and other metallic conducting members under AC current conditions.

Moreover, the carbon nanotubes of the present invention can be provided with a density of from about 0.1 g/cc to about 1.0 g/cc, and more particularly, from about 0.2 g/cc to about 0.5 g/cc. As such, materials made from the nanotubes of the present invention can be substantially lighter in weight. In addition, carbon nanotubes of the present invention can exhibit a Seebeck coefficient that is substantially linear with temperatures, for example, from ambient to at least about 600° C.

It should be noted that although reference is made throughout the application to nanotubes synthesized from carbon, other compound(s), such as boron, MoS₂, or a combination thereof may be used in the synthesis of nanotubes in connection with the present invention. For instance, it should be understood that boron nanotubes may also be grown, but with different chemical precursors. In addition, it should be noted that boron may also be used to reduce resistivity in individual carbon nanotubes. Furthermore, other methods, such as plasma CVD or the like can also be used to fabricate the nanotubes of the present invention.

### Carbon Nanotube Sheets

Although sheets made from carbon nanotubes may be manufactured a similar manner to that described above, sheets of carbon nanotubes may also be made using other processes. For example, Buckey paper may be made by dispersing carbon nanotube “powder” in water with an appropriate surfactant to create a suspension. When this suspension is filtered through a membrane, a type of Buckey paper is created whose properties are illustrated in Table 1 below.

In one embodiment of the present invention, sheets of carbon nanotubes may be stretched to substantially align the carbon nanotubes within each sheet in order to improve properties of the nanotubes. The properties of a carbon nanotube sheet made in accordance with one embodiment of the present invention, and that of a Bucky paper are compared for illustrative purposes in Table 1 below.

TABLE I

| Property | Bucky Paper | CNT Sheet of Present Invention |
|---|---|---|
| Tensile strength | 40 MPa | 800 to 1000 MPa |
| Modulus | 8 GPa | 20-100 GPa |
| Resistivity | 5 × 10−2 Ω-cm | <2 × 10⁻⁴ Ω-cm |
| Thermal conductivity | NA | 65 Watts/m-K |
| Seebeck Coefficient | NA | −60 μV/K n-type to |
| | | 70 μV/K p-type |
| | | (Be₂Te-287 μV/° C. n-type) |
| Figure of Merit | NA | CNT ~0.4 |
| (400° C.) | | (Bi₂Te₃ ~1) |
| ZT = S² * T * σ/TC | | CNT~0.9 normalized by density |
| ZT/ρ(g/cc) | | Bi₂Te₃ ~0.13 normalized |
| S (p/n) = 140 μV/K | | by density |
| σ = 10⁶ S/m | | |
| TC = 20 W/mK | | |
| ΔT = 400 C. | | |

It should be note that, in Table 1, the figure of merit does not contain density or weight. However, since carbon nanotubes sheets can be substantially light, the resulting thermoelectric device or generator can nevertheless be designed with very high power to weight ratio.

It should be appreciated that the sheets from which the thermoelectric device may be made can include, in an embodiment, graphite of any type, for example, such as that from pyrograph fibers. Moreover, the sheets from which the thermoelectric device can be made may include traditional particles or microparticles, such as mesoporous carbons, activated carbon, or metal powders, as well as nanoparticles, so long as the material can be electrically and/or thermally conductive.

### Doping

A strategy for reducing the resistivity, and therefore increasing the conductivity of the nanotube sheets or yarns of the present invention, includes introducing trace amounts of foreign atoms (i.e. doping) during the nanotube growth process. Such an approach, in an embodiment, can employ known protocols available in the art, and can be incorporated into the growth process of the present invention.

In an alternate embodiment, post-growth doping of a collected nanotube sheet or yarn can also be utilized to reduce the resistivity. Post-growth doping may be achieved by heating a sample of nanotubes in a N₂ environment to about 1500° C. for up to about 4 hours. In addition, placing the carbon nanotube material over a crucible of B₂O₃ at these temperatures will also allow for boron doping of the material, which can be done concurrently with N₂ to create BₓN_{y}C_{z} nanotubes.

Examples of foreign elements which have been shown to have an effect in reducing resistivity in individual nanotubes include but are not limited to boron, nitrogen, boron-nitrogen, ozone, potassium and other alkali metals, and bromine.

In one embodiment, potassium-doped nanotubes have about an order of magnitude reduction in resistivity over pristine undoped nanotubes. Boron doping may also alter characteristics of the nanotubes. For example, boron doping can introduce p-type behavior into the inherently n-type nanotube. In particular, boron-mediated growth using BF₃/MeOH as the boron source has been observed to have an important effect on the electronic properties of the nanotubes. Other potential sources useful for boron doping of nanotubes include, but are not limited to B(OCH₃)₃, B₂H₆, and BCl₃.

Another source of dopants for use in connection with an embodiment of the present invention is nitrogen. Nitrogen doping may be done by adding melamine, acetonitrile, benzylamine, or dimethylformamide to the catalyst or carbon source. Carrying out carbon nanotube synthesis in a nitrogen atmosphere can also lead to small amounts of N-doping.

It should be appreciated that when doping the yarn or sheet made from nanotubes with a p-type dopant, such as boron, the Seebeck value and other electrical properties may remain p-type in a vacuum. On the other hand, by doping the yarn or sheet with a strong n-type dopant, such as nitrogen, the nanotubes can exhibit a negative Seebeck value, as well as other n-type electrical characteristics even under ambient conditions.

The resulting doped yarn or sheet of nanotubes can be used as a p-type element or an n-type element in the manufacture of a thermoelectric device or generator of the present invention.

### Thermoelectric Effect

Thermoelectric effect can generally be characterized as a voltage difference that exists between two places on a conductor exhibiting a temperature difference. This effect, commonly referred to as the Seebeck effect, is defined as that voltage difference between two points when the temperature difference is 1° K.

To generate power efficiently, the conductor typically needs to have substantially good electrical conductivity, while having poor thermal conductivity. A figure of merit commonly known as Z is defined as:

### (1) Z=(Seebeck Coefficient)*Electrical Conductivity±Thermal Conductivity or

(2) Z=S²*ε/σ. This relationship comes from the consideration of useful power per degree divided by conducted power as shown below.

From the definition of S, the voltage across two points is:

### (3) V=S*ΔT

And the current through the conductor would be:

### (4) I=V/R=S*ΔT/R,

The power generated, not including convection or radiation losses, can be:

(5) Useful Power=I*V=S*ΔT*S*ΔT/(L/ρ*A)=(S*ΔT)²*ρ*A/L≈Constant, where L is the length of the thermoelectric element and A is the cross sectional area and ρ is the resistivity.
(6) The Thermal Power lost down the conductor is given by: Pₗₒₛₛ=σ*A*ΔT/L, where σ is the thermal conductivity.
(7) The ratio of electrical power generated to thermal power lost is the figure of merit, ZT: Ratio=(S*ΔT)²*ρ*A/L/σ*A*ΔT/L=S² ΔTρ/σ=Z*T

### Convection and Radiation

Heat loss from the conductor can impact energy generation. In particular, the lower the heat loss, due to radiation and/or convection, the higher the ΔT and so power of the device can be. Since both radiation losses and convection losses can be proportional to surface area to volume, the desired geometry for a thermoelectric generator may be that of a cylinder (i.e., yarn of nanotube) of short length. However, if the length is too short, then transmission losses can be high, as will be discussed below. As such, the figure of merit should include these types of losses.

### Efficiency

Typically, a ZT value of 1 can indicate that the thermoelectric device is about 50% efficient. A ZT value of 0.1, on the other hand, indicates an efficiency of about 10%. In general, the larger the ZT, the more efficient the device.

Looking at FIG. 3, the relationship between the Seebeck coefficient and a function of ZT is illustrated. In one example, for an n/p junction, the Seebeck coefficient for a thermoelectric device made from carbon nanotubes of the present invention can be about 140 μV/° K. It should be noted that although weight can be important, weight is not a consideration in FIG. 3.

### Specific Power

As noted above, traditional theremoelectric device made with Bi₂Te₃ has a density ranging from about 7.4 g/cc to about 7.7 g/cc, and may reach over 8 g/cc. The thermoelectric device made from nanotubes of the present invention, on the other hand, has a density range of from about 0.1 g/cc to about 1.0 g/cc, and more particularly, from about 0.2 g/cc to about 0.5 g/cc. As such, there can a factor of about 40 and up to about 80 in weight advantage for the carbon nanotubes of the present invention over Bi₂Te₃.

In addition, the Seebeck coefficient for a sheet of, for instance, substantially aligned carbon nanotubes may be from about −130 μV/° K to about −140 μV/° K in a combined p-type and n-type element. As such, a maximum voltage at a ΔT of 200° C., for example, can be about:

ΔV=ΔT*S=200×130×10⁻⁶=26 mV

Moreover, in addition to the high Seebeck effect and a substantially lower density in comparison to traditional material used in thermoelectric devices, the carbon nanotubes of the present invention can also have substantially lower thermal conductivity due to the existence of dual or multiwall nanotubes, or due to the aggregation of the nanotubes into large bundles. As such, the thermoelectric device made with nanotubes of the present invention can achieve relatively high specific power, for instance, greater than about 1000 W/kg and can exceed about 3000 W/kg at a ΔT of about 400° C.

This specific power compares well with that achieved for single junction solar cell based arrays, which may range from about 25 W/kg to about 100 W/kg, as well as the specific power for future multi junction GaAs arrays, which may range from about 200 W/kg to about 1000 W/kg.

It should be appreciated that the Seebeck coefficient can exhibit an almost constant curve relative to temperature above 200° K. Such a property can suggest that at relatively high temperatures, for example, at about 600° C. or higher, the thermoelectric device made from nanotubes of the present invention can likely outperform those made with the more traditional semiconductor materials, such as Bi₂Te₃, since these traditional semiconductor materials can melt at about 556° C.

For most semiconductors, the ZT may vary considerably over a very short temperature interval. However, values of around 1 may be typical. Of the wide variety of semiconductors available, Bi₂Te₃ is often the most employed because of its relatively high ZT. Table II compares the specific ZT for Bi₂Te₃ with that for carbon nanotubes of the present invention.

TABLE II

| Parameter | CNT | CNT/density | Bi₂Te₃ | Bi₂Te₃/density |
|---|---|---|---|---|
| Z (μV/°K) | 70p, 70n or | NA | 54 | NA |
| | 140 for the | | | |
| | element | | | |
| ZT @300 C. | 0.4 | ~1 | 1 | ~0.13 |

As illustrated in FIG. 4, carbon nanotubes can exhibit a Seebeck coefficient that increases at low temperature but can be flat with temperature higher than about 200° C. The Seebeck coefficient is shown for individual nanotubes as a function of temperature up to near ambient temperature. This measured effect uses a relatively small change in temperature in a specimen in which the overall temperature can vary considerably. Such an approach differs from tests in which only the maximum temperature difference is plotted. It should be appreciated that data currently exist in the public domain only for individual tubes, ropes or bundles of tubes and composites, and only within a limited temperature range. Data on yarns and sheets, on the other hand, are reported herein for the first time.

It has been observed and noted above that sheets made from substantially aligned single wall carbon nanotubes, in accordance with an embodiment of the present invention, can exhibit a substantially high Seebeck coefficient, for example, on a same order as individual tubes or bundles. Measurements have been obtained ranging from about 325° K to about 600° K. These measurements are shown in FIG. 5. The Seebeck coefficients measured are with respect to copper contacts and are generally larger than about 60 μV/° K. These values may be marginally higher than for individual tubes, as shown in FIG. 4.

Some of the key thermoelectric parameters for a carbon nanotube material of the present invention in comparison to a semiconductor (Bi₂Te₃) material are listed in Table III.

TABLE III

| Parameter | Bi₂Te₃ | Carbon Nanotube Sheet |
|---|---|---|
| Seebeck Coefficient | 14 μV/<K at 300 K | >60 μV/°K |
| | 50.4 μV/K at 644 K** | (300°K to 700°K) |
| Power Factor | 4 × 10⁻³ W/k2-m | 1.68 × 10⁻³ W/k2-m |
| S²σ | | |
| Figure of Merit (ZT) | 0.8 to 1 | 0.4 |
| Measured | NA | 3 Watts/gram |
| Thermoelectric | | |
| Power/gram | | |

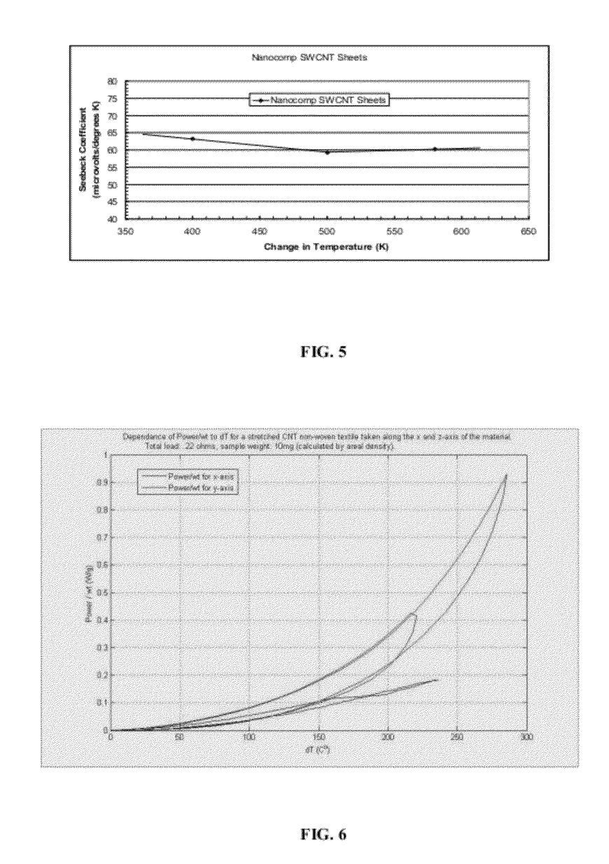

The power output from a thermoelectric device made from a sheet of single-walled carbon nanotubes in contact with a high conductivity metal, such as copper, is shown in FIG. 6. Note that for this device, the power is about 1 W/g. Other specimens, as noted above, have shown up to 3 Watts per gram at a ΔT of 400° C. As a note, a single stage element at ΔT of 400° K provides only 26 mV (65×10⁻⁶*400). These specific power can likely be higher as the temperature increases above 400° C.

Even though the specific power can be relatively high, the practical usable voltage can be low thereby requiring multiple stages or elements or an electronic device that transforms current to voltage.

### Reduced Contact Resistance

Although described above as having n-type and p-type sections separated by metal contacts and the like, the present invention also contemplates a design where the thermoelectric device includes a carbon nanotube substrate having an n-type section on a portion of the substrate and adjacent p-type section on the remaining portion of the substrate. In these embodiments, the n-type section and the p-type sections are in direct physical contact with each other. In designs where an intermediary material is used between the n-type and p-type elements, contact resistance losses may result due to the current flowing between materials having different resistance, for instance, from the n-type material to the intermediary and from the intermediary to the p-type material. As such, direct physical contact between the n-type sections and the p-type sections may reduce contact resistance losses.

In one embodiment, the adjacent n-type and p-type sections are capable of forming a junction whereby a surface may extend across the junction to collect heat radiation, so as to impart a temperature differential between the surface and the remaining areas of the substrate. The temperature differential may allow continuous energy flow from the n-type section to the p-type section. In some embodiments, the surface may collect a substantial portion of heat radiation, such as solar energy, at an angle substantially transverse to the surface of the device, including, for instance, angles of incidence of up to about 85 degrees to normal.

The carbon nanotube (CNT) based thermoelectric device disclosed herein, according to an embodiment, may absorb heat radiation, for example from sunlight or other light sources, and use the heat radiation to generate a current based on a temperature differential in the device between exposed surfaces and unexposed surfaces of the device. For example, given the relatively high Seebeck coefficient of the carbon nanotube materials, the thermoelectric device can produce current due to the temperature difference between relatively high temperature (e.g., hot) junctions on an exposed surface of the carbon nanotube substrate and relatively low temperature (e.g., cold) junctions on the remaining unexposed areas of the carbon nanotube substrate. The temperature difference between the high temperature junctions and low temperature junctions may be driven by either natural (e.g., sunlight) or artificial sources (e.g., a heat source) of heat radiation.

In one embodiment, the substrate of a thermoelectric device may include a single continuous sheet of carbon nanotube material doped to have both n-type and p-type sections, and designed so that the n-type and p-type sections may be in direct physical contact with one another to form a junction there between. In designs where n-type and p-type elements are separated by an intermediary material, contact resistance losses may result as current flows from the n-type sections through the intermediary and to the p-type section thereby decreasing device efficiency. As such, providing n-type and adjacent p-type sections in direct physical contact with one another may minimize contact resistance losses resulting from having an intermediary material at the interface between n-type and adjacent p-type elements. In addition, continuous current flow may be provided in the substrate from the n-type sections to the p-type sections to further improve efficiency of the device as a result of the direct contact between the n-type and p-type sections.

The conversion of heat radiation to electrical energy through doped CNT material may occur in two steps: (1) heat radiation may be absorbed by the CNT material, and (2) the absorbed heat may be converted to electricity via a substantially high Seebeck coefficient of the material. In some embodiments, the heat radiation absorbed in step (1) may come from solar energy or other thermal waste energy. In other embodiments, the heat radiation absorbed in step (1) may come from natural or artificial sources, among others.

In some embodiments, carbon nanotube sheets used in the thermoelectric devices may be prepared in accordance with embodiments of the present invention disclosed in detail herein and further described in U.S. Pat. No. 7,611,579 (filed Jan. 14, 2005), which is incorporated herein by reference.

Generally, the carbon nanotube sheets may include: (1) SWCNT (single-walled carbon nanotube) sheets, (2) MWCNT (multi-walled carbon nanotube) sheets, or (3) DWCNT (double-walled carbon nanotube) sheets, or (4) Boron doped SWCNT, boron doped MWCNT, or boron doped DWCNT. Boron doping can be made possible by introducing trimethoxyboron into the system during the CNT growth process. Each of these processes has certain advantages and disadvantages but all of them can be used to produce CNT-based thermoelectric devices.

Per equation (2) above, substantially high ZT values may be achieved with relatively high electrical conductivity, relatively high Seebeck coefficient and relatively low thermal conductivity. Thus, it is important the Seebeck coefficient be substantially high at a substantially high value of T so that the Carnot efficiency can be maximized. Furthermore, the nature of CNT materials may, for example, enable use at temperatures near about 100° C. and as high as about 490° C. (or perhaps higher) if protected from oxidation.

### Example I

In this example, a thermoelectric device or generator is provided using at least one carbon nanotube sheet made in accordance with an embodiment of the present invention.

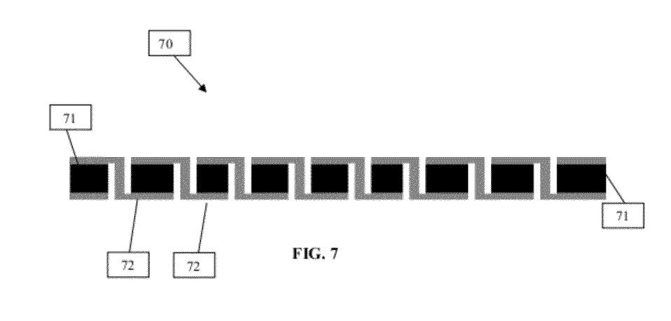

With reference now to FIG. 7, there is shown a schematic diagram of an array 70 of a thermoelectric elements 71 and conducting elements 72 in substantial linear alignment. In one embodiment, elements 71 can be segmented sheets of carbon nanotubes, each sheet 71 doped with a p-type dopant. Alternatively, elements 71 can be a series of sheets 71 of carbon nanotubes, each doped with an n-type dopant. Each sheet 71 may be separated from adjacent sheets 71 by a conductive element 72. It should be appreciated that a plurality of sheets can be used, with each placed on top of one another. This is because, when using a plurality of sheets, the mass can increase, which can result in more power output in the thermoelectric device.

Conducting elements 72, on the other hand, may be made from a metallic material, such as copper, nickel, or other similar conductive materials. In one embodiment, the conductive elements 72 may be coated (e.g., electroplated) on to the thermoelectric elements 71 and subsequently laser cut to provide the segmented pattern as shown. In another embodiment, conductive elements 72 may be made from a nanotube based conductor. The process of coating and laser etching can be similar to those processes known in the art.

Alternatively, rather than using a metallic or nanotube material, a glassy carbon material may be used instead as the conducting element 72. In such an embodiment, lines of a glassy carbon precursor may be printed or placed on to the thermoelectric elements 71. The thermoelectric elements 71 with the glassy carbon precursor material may then be polymerized, in accordance with methods known in the art, to provide a glassy carbon material thereon. This embodiment can act to eliminate contact resistance and enable relatively higher operation temperatures.

To the extent that array 70 requires some stiffness, a high temperature polymer material, such as Torlon, or a polyamide material, may be affixed to the thermoelectric elements 71 and conductive elements 72. The high temperature polymer or polyamide material, in an embodiment, can be substantially thin and can have a thickness ranging from about, 0.001″ to 0.005″. To affix the polymer or polyamide material to the thermoelectric elements 71 and conductive elements 72, a thin film of glassy carbon resin, for instance, malic acid catalyzed furfuryl alcohol may be used to coat the polymer or polyamide material, followed by placement of the array 70 thereonto, then curing.

In an alternate embodiment, stiffness may be provided by initially coating one side of a high temperature polymer or polyamide material with copper, nickel or other similar materials to provide the conductive element 72. Next, the coated polymer or polyamide material can be photoprocessed. The polymer or polyamide material, thereafter, can be coated with a thin film of a glassy carbon resin, such as malic acid catalyzed furfuryl alcohol. A sheet or a stack of sheets of substantially aligned carbon nanotubes can then be affixed onto the polymer or polyamide material to provide thermoelectric elements 71. After curing, the resulting assembly can be laser cut to form linear array 70 of thermoelectric elements 71 and conductive element 72 illustrated in FIG. 7.

Voltage for linear array 70 can be calculated from V=n*50×10⁻⁶*ΔT. In one example, if n=100, and ΔT=250° C., then V=1.25 volts.

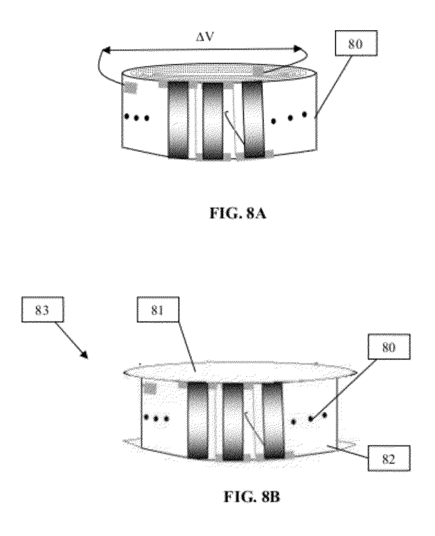

The linear array 70, formed by any of the above embodiments, can then be rolled up about an axis into a disk or core 80 as shown in FIG. 8A. It should be appreciated that in the embodiment where a polymer or polyamide material is not used, when forming core 80, the overlapping layers of the wrapped core 80 can be separated by the higher temperature polymer or polyamide material acting as an insulator, if so desired.

Once formed, the core 80 shown in FIG. 8B can be positioned between a thermal plate 81 attached to a one surface of core 80 and a thermal plate 82 attached to an opposing surface of core 80. It should be noted that one of the plates can act as a hot surface for collecting heat radiation, while the other plate may act as a cool surface for dissipating heat radiation from the hot surface. Thereafter, electrical connections can be made to form a thermoelectric device 83 or generator of the present invention. With such a design, heat collected by, for example, the thermal plate 81 on the top surface can be driven across the core 80 to the thermal plate 82 on the bottom surface due to a temperature differential between the two thermal plates. During the course of heat transfer, the design of core 80 allows it to convert the heat transferred across it into power.

With the ability to convert heat into power, the thermoelectric device 84 can act as a module that can be used for a wide variety of applications. It should be appreciated that this thermoelectric device is defined by a large cross-sectional area and small hot-cold gap spacing. Such a layout provides a substantially high current with the potential for dense packaging, while utilizing a light weight supporting structure. Moreover, the thermal conductivity through the carbon nanotube sheet can also be substantially high, meaning that for applications with limited thermal power input (e.g., solar collection, waste heat collection, etc.) the efficiency and power can be low. However, with unlimited thermal power, the power to weight ratio can exceed 3 W/g.

In one embodiment, the voltage of device 84 can be characterized by:

V=n*26 mV.

Thus, for example, if V=1.4 V and ΔT=200° C. then n=54, if ΔT=400° C., then n=75 per device.

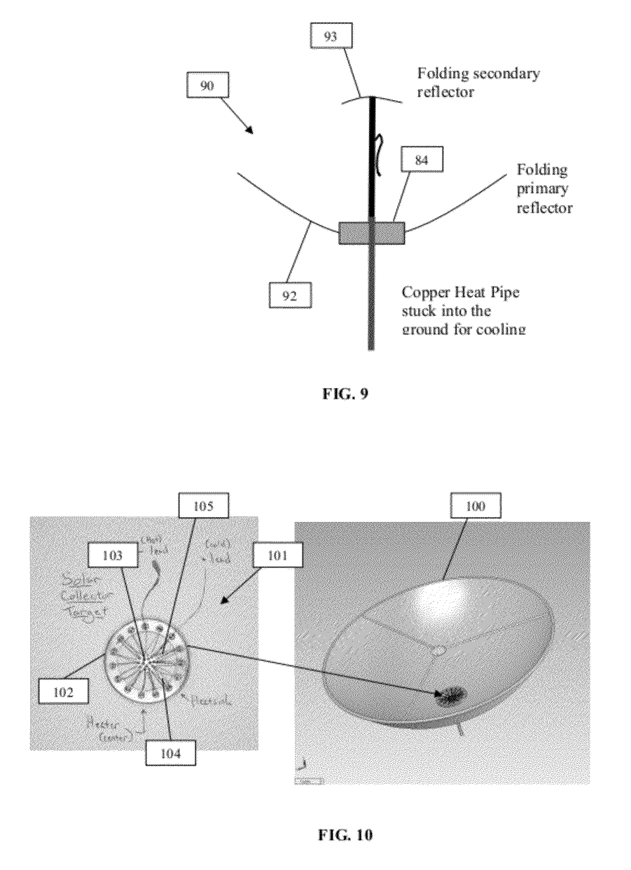

One application for the thermoelectric generator or device 84 is to use it in connection with a small sun collector 90, as shown in FIG. 9. This solar collector 90, as illustrated, includes thermoelectric device 84 placed at the secondary focus of the collector 90. Sun collector 90 can also include reflectors 92 and 93, both of which may be designed to fold out. In an embodiment, reflector 92 may have a 1 inch radius when unfolded, and the entire set up of sun collector 90 may be the size of a pencil. With such a size, sun collector 90 may be used for battery charging applications on one scale with an estimated solar conversion efficiency of at least about 10-15%. Such a conversion efficiency by the sun collector 90 compares favorably with a similar photocell type generator, despite being at a much lighter weight and at lower cost.

In another embodiment, the collector 90 can be designed to produce a few 10's or 100's of mW for battery charging. Larger configurations, of course, can be designed when more power is desired.

Another application for the thermoelectric device 84 or generator shown in FIG. 8B can be used as a large area power generator for houses, buildings, cities etc. For instance, the use of heliostats (or simple concave mirrors) allows the concentration of a significant amount of solar energy into a small area, where a hot end of a thermoelectric generator can absorb the solar energy. In addition, the use of thermoelectric device 84 can allow for relatively high conversion efficiencies of heat to electrical work with no moving parts. Moreover, since the thermoelectric device 84 includes elements 71 and 72 with substantially high chemical stability, device 84 can be durable and can last over a long period.

The thermoelectric device 84 may also be used as a heat or energy engine. In one embodiment, the thermoelectric device 84 can be used as an energy generator from waste heat. In particular, device 84 may be attached so that its hot surface contact a source of waste heat, such as a pipe in a heating system, while its cool surface contact a cold sink, so that heat can be transferred thereto and heat up the cold sink area, and cool down the heat source area. In accordance with one embodiment, if a 1 kg of nonwoven nanotube sheets of the present invention is used to manufacture device 84 for use as a heat or energy engine, such a heat or energy engine can directly convert heat to electrical work, and can put out approximately 1 kW of power. Such a capability allows for a lightweight replacement of, for instance, car and truck alternators, as well as power supplies for marine & aerospace applications. Large scale systems containing a metric ton of nanotubes of the present invention can put out in principle, a megawatt.

The design of such a heat or energy engine can also be used to cool down, for instance a submarine. In particular, the thermoelectric element may be attached to the hot reactor tube of a nuclear submarine on one side, and on the other side to the cold hull of the submarine adjacent to cold ocean water to permit the reactor tube to cool down.

A similar design can be used to incorporate into clothing to transfer heat from the substrate, which acts as the heat source, to cooler environment, such as air, to cool down the wearer.

### Example II

In this embodiment, a thermoelectric device is provided using at least one carbon nanotube yarn made in accordance with an embodiment of the present invention.

Looking now at FIG. 10, a solar collector 100 is provided. The solar collector 100, in an embodiment, includes a thermoelectric device 101 having a outer ring 102 and an inner member 103 concentrically positioned relative to the outer ring 102. Inner member 103, as illustrated, may be a hot plate designed to collect heat from solar rays, while outer ring 102 may be a cool plate designed to dissipate heat. Thermoelectric device 101 may also include a core 104 having at least one carbon nanotube yarn 105, made from a plurality of intertwined nanotubes in substantially alignment. Yarn 105, in an embodiment, extends radially between the inner member 103 and the outer ring 102, and can act as a thermal element. In one embodiment, yarn 105 may be a p-type element or n-type element coated (i.e., electroplated) along its length with a segmented pattern of a metallic material, such as copper or nickel, so that between consecutive coated segments is a segment of non-coated nanotube yarn. The coated segments of yarn 105, in an embodiment, can act as a conductive element, while the non-coated segments of yarn 105 can act as a thermal element. As illustrated, the end of yarn 105 in contact with the hot plate inner member 103 can act as a negative lead, while the opposite end of yarn 105 in contact with the cool plate outer ring 102 can act as a positive lead. Because of its design, the long thin yarn 105 (i.e., thermal element) can be defined by a high gap length and a small cross-sectional area. Such a design, in an embodiment, can allow the solar collector 100 to maximize the difference in temperature between a hot inner member 103 and the cool outer ring 102 by minimizing heat transfer from inner member 103 to outer ring 102. Moreover, since there may be no conducting media, other than the carbon nanotubes yarn 105, the design of solar collector 100 makes it substantially efficient in terms of minimizing waste heat transfer.

### Example III

In this embodiment, a multi-element thermoelectric array is provided using a plurality of carbon nanotube yarns made in accordance with one embodiment of the present invention.

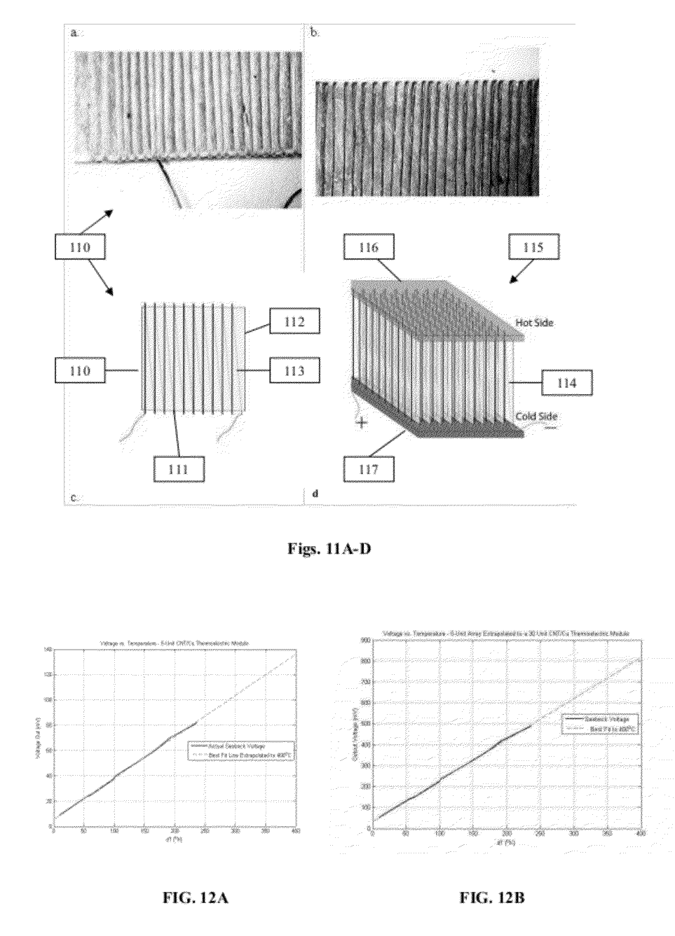

As illustrated in FIGS. 11A-D, a thin thermoelectric panel 110 is provided. The thin panel 110, in an embodiment, includes a plurality of thin thermal elements 111 (FIG. 11C) made from nanotube yarns. In one embodiment, about 30-1000 or more elements 111 having high hot-cold gap length and a small cross-section can be provided on the thin panel 110. These elements 111, designed to act as p-type elements, may be positioned on, for example, a substrate 112 made from, for example, aluminum nitride, mica or other similar material. In an embodiment, the substrate 112 may be coated with copper or nickel on a side on which the carbon nanotube thermal elements are situated (FIG. 11A), while its opposite side remains uncoated (FIG. 11B). On the uncoated side, panel 110 may be provided with a plurality of copper wires 113 acting as n-type elements. In one embodiment, each copper wire 113 may be connected to a corresponding thermal element 111, as shown in FIG. 11C. To the extent desired, a plurality of thin panels 110 may be assembled into a core 114 of for use as a thermoelectric device 115, as illustrated in FIG. 11D. Such a device 115 includes a first plate 116 acting as a hot surface, and a second plate 117 acting as a cool surface. Plates 116 and 117, in an embodiment, may be made from heat conducting materials, such as alumina. With such a design, heat collected by the first plate 116 can be driven across the core 114 to the second plate 117 due to a temperature differential between the first plate 116 and the second plate 117. During the course of heat transfer, the design of core 114 allows it to convert the heat transferred across it into power.

Although shown with a plurality of panels 110, it should be noted that device 115 can include just one panel 110, and that the device 115, including the thermoelectric panel 110, can be used or designed to have any of a number of other configurations. In addition, nickel wires 113 may be used in place of copper wires 113, or n-type nanotube yarns can be used in place of wires 113.

This design of panel 110 can be mechanically robust. In an embodiment, in order to obtain, for instance, 1.5 volts at about a ΔT of 400° K, the number of thermal elements 111 utilized within panel 110 may be about 58. Moreover, in a vacuum, the panel 110 has the potential for a wide range of operating temperatures, from the highest to perhaps the lowest of operating temperatures. In addition, the highly dense array of thermal elements 111 can give the panel 110 a substantially high operating voltage per unit of heated area in comparison to any of the designs provided above. In an embodiment, if spacing of thermal elements 111 is too close, then cold junctions in panel 110 may need to be heated to raise the temperature.

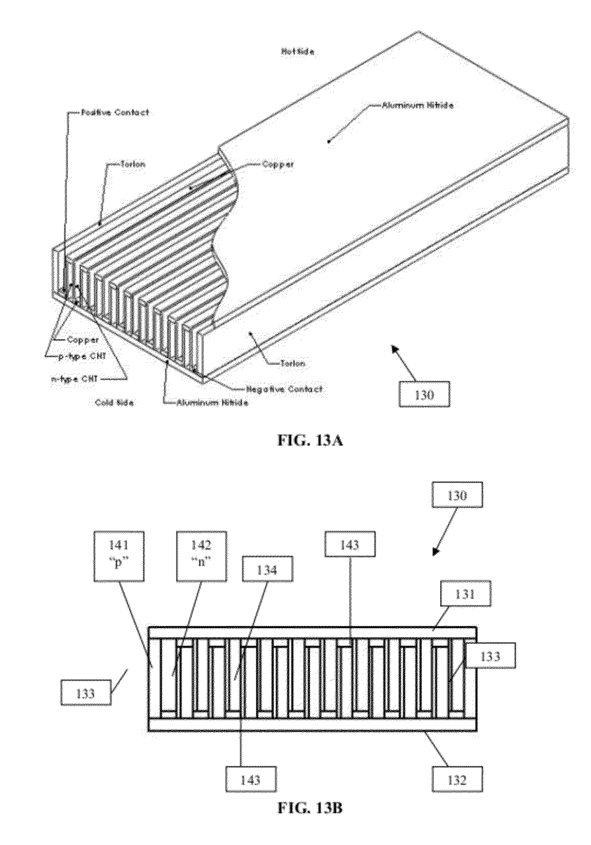

FIGS. 12A-B illustrate data obtained from a panel having an array of thermal elements 111. In particular, data from a 5 element panel and from a 30 element panel are illustrated in FIG. 12A and FIG. 12B respectively. These panels, similar to panel 110 above, includes a coated side having p-type carbon nanotube thermal elements, and an uncoated side having copper or nickel n-type elements. In an embodiment, these panels may be about 1 cm by 1 cm in size. Alternatively, the copper or nickel n-type elements can be substituted with n-type nanotube yarns. Note the y-axis scale differences between the two arrays.

### Example IV

In space-related applications, a geometry, such as that shown in FIGS. 11A-D may be able to handle substantially high power. In particular, in space, radiation can be used for cooling. For example, placing an insulated reflector on the back side of the substrate 112 and suspending the carbon nanotube yarns (i.e., elements 111) above this reflector can be used for high heat transfer. Further, in accordance with an embodiment, by heating p-type nanotubes in vacuum, it is possible to reversibly transformed p-type nanotubes to n-type. In other words, exposing the p-type nanotubes to a vacuum environment at an elevated temperature can transform such nanotubes to n-type. On the other hand, doping the p-type nanotubes can permanently stabilize them. Accordingly, by making device 115, as shown in FIG. 11D, from a single yarn and appropriately masking it during the doping operation, a substantially high Seebeck coefficient array can be made that is capable of generating high power for space applications.

This geometry can also be modified by introducing a reflector on the back surface and doping the nanotubes after growth with boron using a selective masking technique.

### Example V

Waste heat is essentially a free, readily-available source of energy which can be converted into useful forms through an energy harvesting device of the present invention.

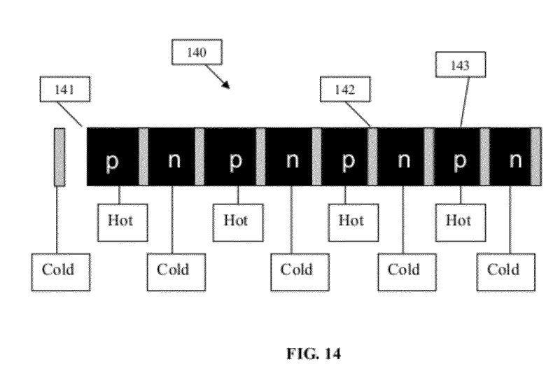

FIGS. 13A-B illustrate one possible configuration of a thermoelectric device 130 useful for energy harvesting. Device 130, as shown, includes a top plate 131 and a bottom plate 132, both of which may be made from, in an embodiment, heat-conducting alumina, such as aluminum nitride. In one embodiment, top plate 131, for instance, can act as a hot surface for collecting heat radiation, while the bottom plate 132 can act as a cool surface for dissipating heat radiation from the top plate 131. Thermoelectric device 130 also includes supports 133 situated between top plate 131 and bottom plate 132. Supports 133, in one embodiment, may be made from a low-thermal-conductivity material, such as Torlon. Device 130 further includes a core 134 situated between supports 133 and extending from the top plate 131 to the bottom plate 132. In an embodiment, core 134 may be provided with a design such as that illustrated in FIG. 14. Specifically, core 134 may include a nanotube sheet having one segment doped with a p-type dopant and an adjacent segment doped with an n-type dopant, in an alternating pattern to provide a linear array 140 of alternating p-type elements 141 and n-type elements 142. Moreover, as illustrated, between adjacent p-type element 141 and n-type element 142, a conducting element 143 can be provided to join the p-type element 141 with the n-type element 142. Furthermore, one end of linear array 140 can be designed to act as a positive contact, while the opposite end can act as a negative contact (See FIG. 13A).

With particular reference now to FIG. 13B, in the embodiment shown, the core 134 can include a series of nine alternating “n” and “p” type thermal elements 141 and 142 made from a carbon nanotube sheet. The nanotube sheet, in one embodiment, can be folded accordion style and placed between the supports 133, such that every other conducting element 143 is in contact with the hot top plate 131, while each of the remaining adjacent conducting elements 143 is in contact with the cool bottom plate 132.

Although shown with nine alternating “n” and “p” type elements, it should be appreciated that, if desired, core 134 can be made to have more than or less than the nine alternating “n” and “p” type elements shown. Moreover, rather than just one nanotube sheet, a plurality of nanotube sheets having alternating “n” and “p” type elements may be used. When utilizing a plurality of nanotube sheets, each sheet may be placed on top of one another, or each sheet placed adjacent to and in parallel to one another, or both. Regardless of the arrangement of the sheets, when using a plurality of sheets, the mass of core 134 can increase, which can result in more power output in the thermoelectric device 130.

To provide the doped pattern in array 140, in one embodiment, the n-type elements 142 may be doped (i.e., chemically treated) with chemicals or chemical solutions that can act as electron donors when adsorbed onto the surface of the nanotubes, making the resulting n-type elements 142 electron-doped. Examples of such chemicals or chemical solutions include polyethylenimine (PEI) and hydrazine. Other chemicals or chemical solutions can also be used. Of course, traditional doping protocols may instead be used.

Table IV illustrates solutions used and their effect on carbon nanotube materials.

TABLE IV

| | | | | | Seebeck |
|---|---|---|---|---|---|
| | | | | | after |
| Sam- | | Starting | Ending | | Secondary |
| ple | | Seebeck | Seebeck | Secondary | Treatment |
| # | Treatment | (uV/K) | (uV/K) | Treatment | (uV/K) |
| 1 | Polyethylenimine | 32 | −58 | Bake 2 hr | 75 |
| | (PEI, | | | @ 250 C. | |
| | H(NHCH₂CH₂)nNH₂) | | | | |
| | 20 wt % in EtOH | | | | |
| 3a | Tri-octyl phosphene | 32 | −14 | | |
| | (TOP, | | | | |
| | [CH₃(CH₂)₇]₃P) | | | | |
| | 20 wt % in EtOH | | | | |
| 3b | Tri-octyl phosphene | 32 | −62 | Bake 2 hr | 70 |
| | (TOP) 20 wt % | | | @ 325 C. | |
| | in Hexane | | | | |
| 3c | 100% TOP | 32 | −61 | | |
| 4a | Tri-phenyl phosphine | 32 | −15 | | |
| | 20 wt % in acetone | | | | |
| 5 | Hydrazine, NH₂NH₂ | | | | |
| 6 | Ammonia, NH₃ | | | | |
| 7 | Aniline, C₆H₅NH₂ | | | | |
| 8 | Sodium Azide, NaN₃ | | | | |
| 9 | Melamine, C₃H₆N₆ | | | | |
| 10 | Acetonitrile, CH₃CN | | | | |
| 11 | Benzylaime, | | | | |
| | C₆H₅CH₂NH₂ | | | | |
| 12 | Polyvinylpyrrolidone | | | | |
| | ((PVP, (C₆H₉NO)ₙ) | | | | |
| 13 | N-Methylpyrrolidone | | | | |
| | (NMP, C₅H₉NO) | | | | |
| 14 | Polyaniline | | | | |
| 15 | Amino butyl | | | | |
| | phosphonic acid | | | | |

In one embodiment, treatment of n-type elements 142 can be as follows. Strips of copper 143 are electroplated onto the a carbon nanotube sheet to divide it into distinct sections. Every other section, in an embodiment, can be doped to n-type 142, as shown in FIG. 14. The sections to be n-type are then treated with a concentrated electron-rich solution of one of the chemicals listed in Table IV. After the n-type sections are carefully rinsed, the strip is folded, accordion-style and soldered between the two alumina plates 131 and 132. The Seebeck coefficient produced from the “n” and “p” type sections is, respectively, −60 μV/° K and 70 μV/° K, which gives a total of 130 μV/° K per element.

This device can also be used as a Peltier device, using the flow of electrons or holes within the thermoelectric material to pump heat from one side of the device to the other. The internal thermoelectric element can be modified slightly from the energy harvesting version to increase the efficiency. The treatment remains the same as above with the exception that a multi-layered piece of nanotube material may be used (thickness of about 1-2 mm) with the nanotube materials placed on top of one another. Short, square elements can then be cut from the treated nanotube material and soldered between the alumina plates, thus increasing the contact area between the thermoelectric material and the alumina.

### Example VI

In one embodiment, a thermoelectric device is disclosed using at least one carbon nanotube sheet fabricated in accordance with an embodiment of the present invention.

### Carbon Nanotube Substrate

Reference is now made to FIG. 15 showing a perspective view of a carbon nanotube substrate 210 including an n-type section 212 on a portion of the substrate 210, and an adjacent p-type section 214 on the remaining portion of the substrate 210. The substrate 210, in an embodiment, can be fabricated by doping a single continuous strip of carbon nanotubes 230 (e.g., tape or sheet) such that adjacent n-type section 212 and p-type section 214 can be provided in direct physical contact without an intermediary material between the p-type and n-type sections. Furthermore, direct physical contact between the n-type and p-type sections may allow continuous energy to flow from the n-type section 212 to the p-type section 214 thereby increasing the efficiency of the thermoelectric device 200.

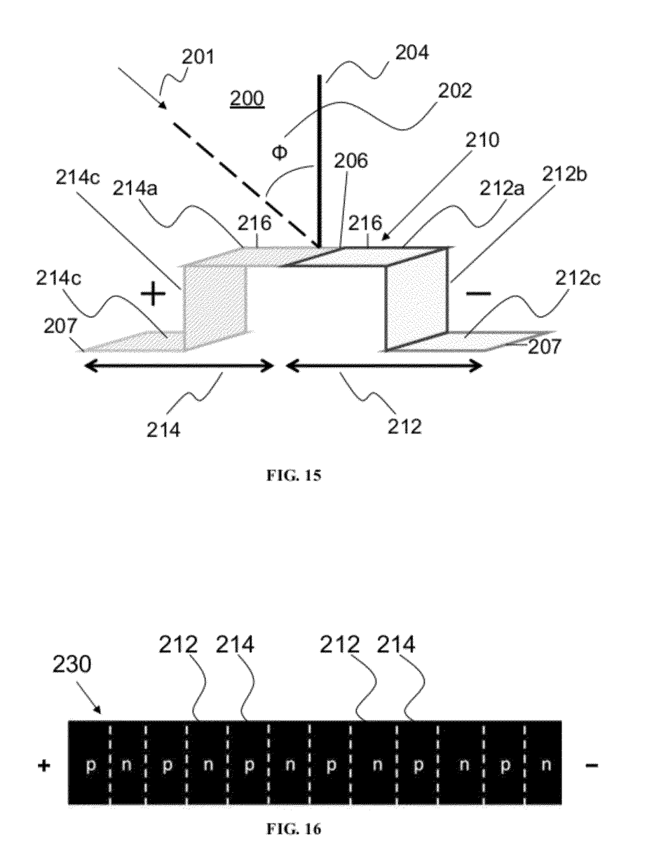

Although FIG. 15 shows the device 200 with only one n-type section 212 and one adjacent p-type section 214, it should be noted that the substrate 210 of the device 200 can include a plurality of adjacent n-type and p-type sections arranged in continuous, alternating pattern substantially such as that shown in FIG. 16.

Reference is now made to FIG. 16 showing a single continuous strip of carbon nanotubes 230 doped to have alternating n-type 212 and p-type 214 sections. Although FIG. 16 shows, in an embodiment, a single continuous strip 230 having six p-type sections 214 and six n-type sections 212, it should be noted that the strip 230 can be designed to have any number of p-type and n-type elements. By doping a single continuous strip of carbon nanotubes 230 to produce adjacent, alternating p-type and n-type sections in direct physical contact, contact resistance losses at the p-n junctions may be reduced thereby permitting continuous flow of energy (e.g., current) from the n-type sections to the p-type sections. In this manner, a thermoelectric device, according to one embodiment of the present invention, may provide increased efficiency due to the continuous flow of energy through the device.

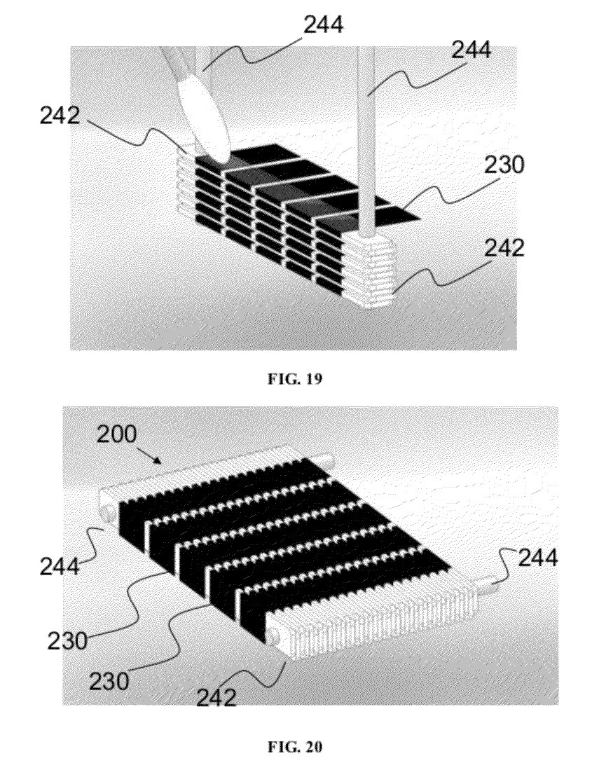

In an embodiment, the device 200 can also be designed with multiple carbon nanotube substrates 210 with multiple n-type sections 212 and adjacent p-type sections 214 forming continuous, alternating patterns, such as shown in FIG. 20. Although FIG. 20 shows five continuous strips of carbon nanotubes 230 folded in the shape of an accordion to form five carbon nanotube substrates 210, it should be appreciated that the device 200 may be designed with other configurations including fewer or more strips of carbon nanotubes 230.

For example, because current typically flows from negative to positive, the direction of current flow may be tailored for a particular strip depending on the sequence of doped p-type and n-type sections. In general, n-type sections are associated with the negative end (V⁻) while p-type sections are associated with the positive end (V⁺). Thus, current typically flows from n-type sections to p-type sections. Therefore, a strip having doped sections arranged n-p-n-p in continuous, alternating pattern, can be provided with current flowing (e.g., from left to right in this example) in an opposite direction from a strip having doped sections p-n-p-n arranged in continuous, alternating pattern (e.g., from right to left in this example). It should be noted that the current quantity can be determined by the resistivity of the material and the length of the series of elements.

Still referring to FIG. 16, in one embodiment, a thermoelectric device 200 having multiple carbon nanotube substrates 230 may be provided such that each substrate (e.g., strip, sheet, or yarn) can be oriented in the same direction. For example, a first strip or sheet 230 may be oriented n-p-n-p or p-n-p-n such that each n-type 212 and adjacent p-type section 214 on the first strip or sheet 230 can be aligned parallel with and adjacent to each n-type 212 and adjacent p-type section 214 on a second strip or sheet 230. In another example, adjacent strips or sheets 230 may be arranged to form a matrix such that every other strip or sheet 230 may be oriented in the opposite direction so that current may flow in two directions. In particular, a first strip or sheet 230 may be oriented n-p-n-p while a second strip or sheet 230 may be oriented p-n-p-n such that the strips or sheets 230 can be adjacent and aligned with each other. Additional strips or sheets 230 may be introduced in continuing alternating pattern such that p-type sections can be adjacent to n-type sections throughout the matrix. In this manner, continuous current may flow, for example, from n-type sections to p-type sections along two axes (e.g., X and Y). Other configurations may also be employed as desired. For example, a three-dimensional matrix with multiple matrices stacked on top of each other may be designed to provide current flow from n-type sections to p-type sections along three axes (e.g., X, Y, and Z).

Referring again to FIG. 15, in some embodiments, the carbon nanotube substrate 210 may be made from one of single-walled carbon nanotubes (SWCNT), double-walled carbon nanotubes (DWCNT), or multi-walled carbon nanotubes (MWCNT), among other carbon nanotube configurations. In some embodiments, carbon nanotubes may be boron doped during fabrication to increase the conductivity of the nanotubes. For instance, carbon nanotube substrate 210 may be made from one of boron-doped SWCNTs, boron-doped DWCNTs, or boron-doped MWCNTs. In other embodiments, carbon nanotubes may be stretched during fabrication to substantially align the nanotubes in a uniform direction so as to increase their conductivity. Stretching carbon nanotubes is described in detail in U.S. Patent Application Publication No. 2009/0075545 filed on Jul. 9, 2008, which is incorporated herein by reference. For example, carbon nanotube substrate 210 may be made from one of stretched SWCNT, stretched DWCNT, stretched MWCNT, boron-doped and stretched SWCNT, boron-doped and stretched DWCNT, or boron-doped and stretched MWCNT, among others.

In some embodiments, the carbon nanotube substrate 210 (e.g. strips, tapes or sheets) may further be doped in accordance with the doping strategies described above. Although carbon nanotubes may naturally p-dope upon contact with oxygen, in one embodiment, additional hole doping can be performed. In another embodiment, the p-type section may be defined by doping a portion of the substrate 210 with tetracyanoquinodimethane (TCNQ). In an embodiment, the p-type section can be formed by exposing the substrate 210 to oxygenated atmosphere. Alternatively, the p-type CNT strip can be formed by heat treating in air. In some instances, electron doping may be carried out after hole-doping has been performed. In an embodiment, the n-type section 212, may be defined by doping a portion of the substrate 210 with polyethylenimine (PEI). In another embodiment, the n-type section 212, can be formed by doping the substrate 210 with poly(phenylene sulfide) (PPS). In yet another embodiment, the n-type section 212, may be made by nickel plating the substrate 210. Such a plated metal may be operated in air at relative high temperatures, with a relative lower Seebeck coefficient. By doping a single continuous substrate 210 of carbon nanotubes with additional holes to include p-type sections and doping the same strip with additional electrons to include adjacent n-type sections, substrate 210 may be formed with p-type and n-type sections in direct physical contact to substantially eliminate contact resistance losses and provide substantially continuous current flow from the n-type to the p-type sections. In some instances, minimizing contact resistance losses may also improve device efficiency.

Referring next to FIG. 16, in one embodiment, a single continuous strip of carbon nanotubes 230 may be doped with TCNQ so that the Seebeck coefficient of the p-type sections can be 70 μV/K. The same treated strip 230 can be subsequently doped with PEI so that the Seebeck coefficient of the n-type sections can be −50 μV/K. Thus, by doping a single continuous strip of carbon nanotubes 230 with TCNQ to include p-type sections, and doping the same tape with PEI, to include adjacent n-type sections, the strip 230 may be formed with p-type and n-type sections in direct physical contact to eliminate contact resistance and provide continuous current flow from the n-type to the p-type sections such that a Seebeck coefficient of 120 μV/K (absolute value of |70 μV/K−50 μV/K|) can be achieved for the carbon nanotube strip 230.

In another embodiment, a thermoelectric device 200 fabricated using a carbon nanotube strip 230 may achieve a ZT value of approximately 0.24. For example, assuming a Seebeck coefficient (S) of 120 μV/K for the doped nanotube strip 230 (see above), with electrical conductivity (ε) of 10⁶ S/m, mean temperature (T) of 323K, and thermal conductivity of 5 W/m-° K, the figure of merit ZT may be calculated as follows:

$$ZT = {S}^{2} * ɛ * T / κ ( for a single material )$$

$$\begin{matrix}ZT = {( {S}_{p} - {S}_{n} )}^{2} / {( √ {ρ}_{p} {κ}_{p} + √ {ρ}_{n} {κ}_{n} )}^{2} ( for a junction ) \\ = ( 14400 \times {10}^{- 12} ) {10}^{6} ( 323 ) / ( 4 \times 5 ) \\ = 2.41 \times {10}^{- 1} \\ = 0.24 ∼ 1 / 4\end{matrix}$$

### Fabrication

Once carbon nanotube substrate 230 (e.g., strip, tape, sheet, or yarn) having doped n-type sections and adjacent p-type sections in alternating, continuous pattern has been formed (as shown in FIG. 16), the substrate 230 may be folded in the shape of an accordion substantially similar to that as shown in FIG. 15.

Reference is now made to FIG. 18 illustrating five doped carbon nanotube substrates 230 prior to being folded into the accordion shape. Although five substrates 230 are shown, it should be noted that any number of substrates 230 can be used as desired.

FIG. 19 illustrates the carbon nanotube substrates 230 in the process of being folded using removable plates 242 to form a plurality of surfaces 216 substantially similar to that as shown in FIG. 15. The surfaces 216 are capable of extending across junctions between the p-type and adjacent n-type section, whereby the surfaces 216 may be designed to collect heat radiation. In some embodiments, the surfaces 216 may also allow the collected heat radiation to create a temperature differential between the surfaces 216 and the remaining areas of the substrate 230. Given the relatively high Seebeck coefficient of the carbon nanotube material used, continuous energy flow from the n-type section to the p-type section may be achieved in proportion to the temperature differential facilitated by the collected heat radiation. It should be appreciated that substrates 230 may be folded across the removable plates 242, as often as desired, until a thermoelectric device 200 such as that substantially shown in FIG. 20 may be obtained.

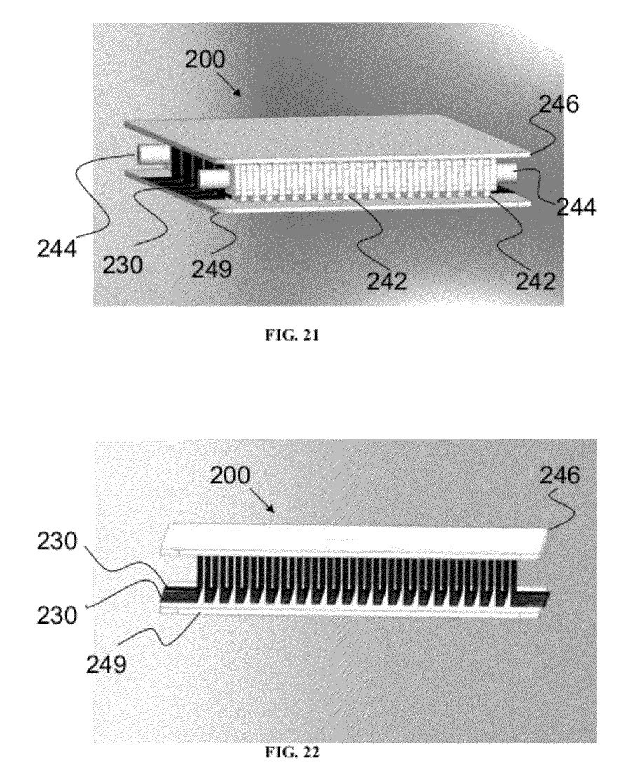

Turning now to FIG. 21, in another embodiment, a member 246 may be bonded to the surfaces of substrates 230 with removable plastic plates 242 in place. The member 246 can be provided, in an embodiment, for collection of heat radiation. In another instance, the member 246 may facilitate generation of temperature differential in device 200, as described above. In this embodiment, a member 249 may also be bonded across surfaces of substrates 230 opposite the member 246 to dissipate heat radiation collected by the member 246. Once member 246, and if desired, member 249, have been bonded, a bonding agent may be used to cure and strengthen the bonding. Optionally, the plates 242 may be removed from device 200. In one embodiment, the member 246 may function substantially similar to that of a hot plate or heat source to facilitate the collection of heat radiation. In another embodiment, the member 249 may function substantially similar to that of a cold plate or heat sink to facilitate the dissipation of heat radiation from the hot plate or heat source (e.g., member 246).

Reference is now made to FIG. 22 illustrating one embodiment of a thermoelectric device 200 with the plates 242 and the supports 244 removed.

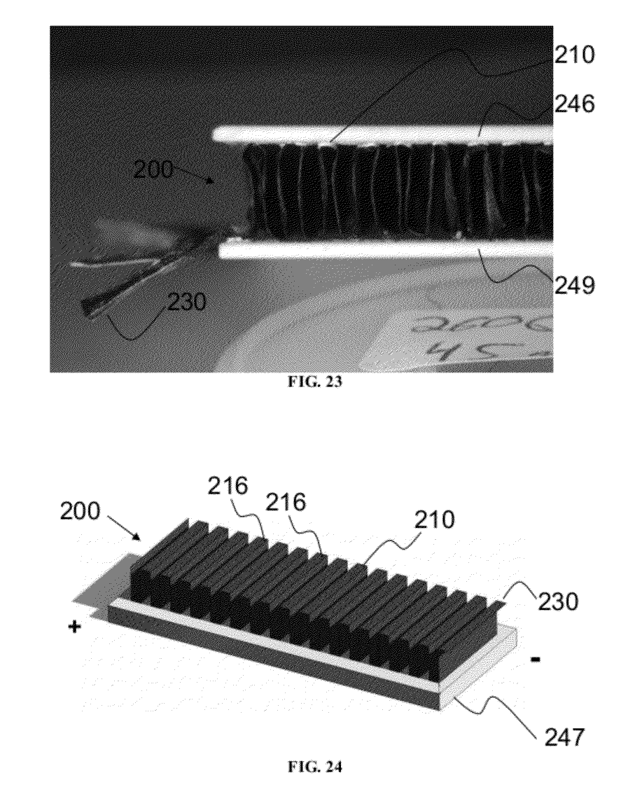

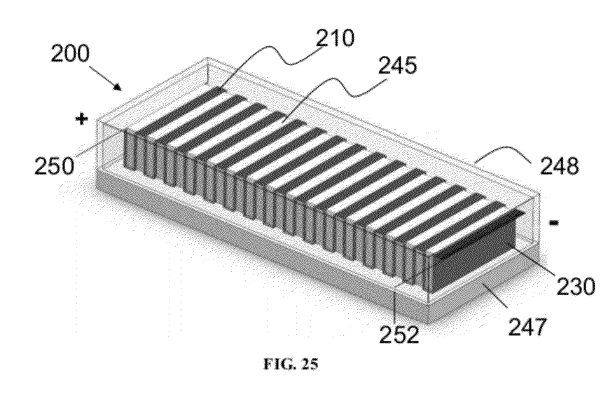

In some embodiments, the thermoelectric device 200 may subsequently be filled with epoxy, polyurethane foam or aerojel insulation 245 as substantially shown in FIG. 25. In other embodiments, spaces between the substrate or substrates 230 within the thermoelectric device 200 may be left unfilled as substantially shown in FIG. 24. It will be appreciated by one skilled in the art that other filler materials may be used to make the thermoelectric device 200 more sturdy or provide additional structural support.

### Performance

Returning now to FIG. 15, a thermoelectric device 200 may also include a surface 216 for collecting heat radiation 201. In particular, the surface extends across a junction 206 formed between n-type section 212a and adjacent p-type section 214a to collect heat radiation so as to create a temperature differential between the surface 216 (as defined by n-type section 212a and p-type section 214a) and the remaining areas of the substrate 210 (as defined by n-type section 212c and p-type section 214c). More particularly, as heat radiation 201 (e.g., sunlight, light, heat) impinges on the surface 216, the carbon nanotube substrate 210 may act like a black substrate and absorb substantially all the radiation as heat. Once absorbed, heat may be converted to electricity proportional to a temperature differential (ΔT) between temperature T₁ near junction 206 on the surface 216, and a temperature T₂ near junctions 207 near n-type section 212c and p-type section 214c.

By creating a temperature differential, e.g., the temperature difference between a first temperature T₁, or relatively higher temperature (e.g., hot) junction 206, and a second temperature T₂, or a relatively lower temperature (e.g., cold) junction 207, a continuous energy flow of induced current from the n-type section 212 to the p-type section 214 may result. In particular, given the substantially high Seebeck coefficient of the nanotube material used to form carbon nanotube substrate 210, heat radiation absorbed by the nanotube material may be converted to current due to a voltage created by the temperature differential between the hot junctions 206 and cold junctions 207.

For example, according to Equation (3) above, for a device having a single p-type and a single n-type element, and a Seebeck coefficient of 120 μV/K, as described above in an embodiment and as substantially shown in FIG. 15, assuming a ΔT of 1K, the voltage induced in the device upon absorbing heat radiation can be about:

V=120 μV/K*2*1=240 μV

It should be appreciated that devices 200 having multiple strips or sheets, as substantially shown in FIG. 20, can operate in substantially similar manner. In particular, by directing heat radiation to the p-n junctions on surfaces of the carbon nanotube strips or sheets, and given the high Seebeck coefficient of the carbon nanotube material, heat radiation may be absorbed and a temperature differential created between the surfaces and the remaining areas of the strips or sheets such that a continuous flow of energy from the n-type sections to the p-type sections results. The continuous flow of energy can generate power, current, and voltage, to name a few.

### Energy Generation

Still looking at FIG. 15, for use in generating energy, thermoelectric device 200 may be exposed to heat radiation, such as sunlight, and angled in a direction so that heat radiation can strike the device at a substantially normal angle of incidence 204 for the maximum period of time. In another embodiment, thermoelectric device 200 may be mounted at an angle such that the heat radiation e.g., sunlight 201 can be directed to surface 216 of carbon nanotube substrate 210. In particular, heat radiation may be directed to an area extending across junction 206 between n-type section 212a and adjacent p-type section 214a so as to create a temperature differential between the area exposed to the heat radiation e.g., surface 216, and the remaining areas of the substrate, including p-type sections 214b and 214c and n-type sections 212b and 214c. In one embodiment, heat radiation may be directed to surface 216 to create a temperature differential between junction 206 and junctions 207 adjacent p-type section 214c and n-type section 212c.

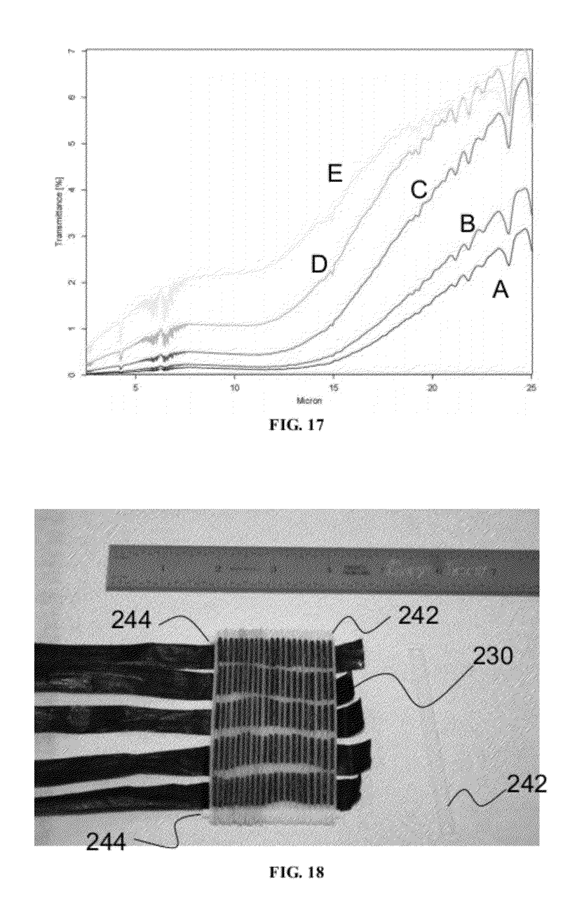

Referring again to FIG. 17, there is shown the reflectance of heat radiation 201 at varying angles of incidence (φ) 202 for, in an embodiment, the multiwall carbon nanotube material used to manufacture a thermoelectric device 200 of the present invention. Line A, the lowest line, shows reflectance of heat radiation 201 using a dummy holder with mirror sample at 45 degrees. Line B show reflectance of heat radiation 201 at a an angle of incidence (φ) 202 of about 45 degrees to normal 204. Line C shows reflectance of heat radiation 201 at a an angle of incidence (φ) of about 50 degrees to normal 204. Line D shows reflectance of heat radiation 201 at an angle of incidence (φ) 202 of about 70 degrees to normal 204. Line E, the highest line, shows reflectance at an angle of incidence (φ) of about 80 degrees to normal 204. As illustrated, as long as heat radiation strikes the thermoelectric device 200 at an angle of incidence 202 of less than about 80° (e.g., normal angle or 0° angle of incidence, 15°, 25°, 30°, 50°, the reflectance may be less than 2%, and the absorbance better than 98%. It should be appreciated, however, that at 3.2 microns wavelength, even at an angle of incidence (φ) beyond 80°, most of the heat radiation 201 can be absorbed (e.g., low transmittance of less than 2%). Thus, in an embodiment, the surface 216, may be able to collect a substantial portion of the heat radiation 201, e.g., solar energy, at an angle of incidence (φ) 202 of up to about 85 degrees.

In some embodiments, the angle of incidence 202 that may be collected by the device 200 may be up to about 89 degrees, or up to about 88 degrees, or up to about 87 degrees, or up to about 86 degrees, or up to about 84 degrees, or up to about 83 degrees, or up to about 82 degrees, or up to about 81 degrees. In other embodiments, the angle of incidence 202 that may be collected by the device 200 may be in the range of from about 0 degrees to about 80 degrees, or from about 0 degrees to about 85 degrees, or from about 0 degrees to about 75 degrees, or from about 0 degrees to about 45 degrees, or from about 35 degrees to about 85 degrees, or from about 35 degrees to about 80 degrees, or from about 45 degrees to about 80 degrees, or from about 60 degrees to about 75 degrees.

Although the angle of incidence 202 is only shown for one side of the device, it will be understood by one skilled in the art that the same principle applies on both sides and that the heat radiation 201 absorbed may be substantially transverse with respect to the device 200.

### Carbon Nanotube Yarns

In an embodiment, substrate 210 may be made from carbon nanotube yarns such that the yarns are all doped on one side n-type and on the other side p-type. In this manner, device 200 may be provided with the potential to generate less power but higher voltage. Thus, device 200 may be custom tailored as a voltage source or power source depending on the application. In an embodiment, thermoelectric device 200 may be used for generating power. In another embodiment, device 200 may be used as a current source. In yet another embodiment, thermoelectric device 200 may be used as a source of voltage. Using carbon nanotube yarns, made in accordance with an embodiment of the invention, requires no weaving and thus may provide for simpler fabrication.

### Harvesting Waste Heat

With respect now to FIG. 22, there is illustrated a thermoelectric device 200 for harvesting waste heat using at least one carbon nanotube substrate made in accordance with an embodiment of the present invention. The thermoelectric device 200, for harvesting waste heat may be capable of collecting and converting waste heat sources directly to electricity. In an embodiment, a member 246 may be positioned across the top surfaces of carbon nanotube strip 230 (folded in the shape of an accordion) to collect heat radiation. In an embodiment, a member 249 can be positioned across the bottom surfaces of carbon nanotube strip 230 (folded in the shape of an accordion) to dissipate heat radiation from the carbon nanotube strip 230. In an embodiment, a member 246 may be positioned across top surfaces of strip 230 to collect heat radiation, and a member 249 may be positioned across bottom surfaces of strip 230 to dissipate the heat radiation collected by member 246. In another embodiment, a member 246 can be attached to a hot junction while the other junction (e.g., cold) may be allowed to radiate to the environment. In an embodiment, members 246 and 249 may be made from anodized aluminum. In an embodiment, members 246 and 249 may be made from aluminum nitride. In an embodiment, members 246 and 249 may be made from aluminum oxide. In some embodiments, a heat source may be positioned adjacent a surface of member 246 as an additional source of heat radiation to generate a temperature differential in device 200.

Now looking at FIG. 23, there is shown a cross sectional view of an actual device constructed according to an embodiment of the present invention. As can be seen in FIG. 23, there are numerous junction strips 230, which can be tested individually.

### Direct Solar to Energy

With respect now to FIG. 24, there is illustrated a thermoelectric device 200 for direct conversion of solar energy e.g., heat radiation, to energy (e.g., current or electricity) using at least one continuous carbon nanotube strip 230 or substrate 210 made in accordance with an embodiment of the present invention.

As shown in FIG. 24, in an embodiment, the top member 246 (not shown) may be left off in order to allow the carbon nanotube strip 230 to be exposed to sunlight directly. By leaving off the top lid and allowing sunlight (or any electromagnetic radiation) to impinge onto the strip 230, the strip 230 can act like a black substrate and absorb substantially all of the sunlight. To that end, substantially all of the electromagnetic radiation e.g. heat radiation, hitting the sheet exposed on the surfaces 216 may be converted to heat. For example, in space applications, the radiant intensity can be as much as 1360 W/m². On the other hand, on the surface of the earth the radiant intensity can vary from 400 to 750 W/m² depending on weather, latitude, time of year, or other variable factors.

In another embodiment, a thermoelectric device 200 for maximizing heat radiation absorption using at least one continuous carbon nanotube strip 230 (e.g., plurality of carbon nanotube substrates 210 shown in FIG. 15) made in accordance with an embodiment of the present invention is provided.

With particular reference now to FIG. 25, in an embodiment, the strip 230 folded in the shape of an accordion, may be enclosed in a casing 248. In an embodiment, the casing 248 may be made from a PV-quality glass or other similar material, in order to protect, and further heat the carbon nanotube material. By enclosing the carbon nanotube strip 230, the thermoelectric device 200 of this embodiment may allow the largest possible quantity of heat radiation 201 to pass through while trapping the radiation once the radiation enters inside the casing. In an embodiment, the thermoelectric device 200, may be provided with a heat sink such as a thin anodized aluminum sheet (not shown). In an embodiment, the heat sink may be optimized to draw away the maximum amount of heat while maintaining the maximum possible temperature difference ΔT between Tₕₒₜ and T_{cold} (e.g., ΔT=T₁−T₂ as shown in FIG. 15) on the carbon nanotube strip 230. Utilizing this design may allow the device 200 to conform to non-flat surfaces. For example, the device may be wrapped around a hot water pipe. In an embodiment, the heat sink may also be a larger finned anodized aluminum block, or base 247, particularly, for applications where a flexible solar powered thermoelectric cell may be desirable.

### Exhaust Based Thermoelectric Power Generator

Turning to FIG. 26, a thermoelectric device 2600 may be used to collect energy from waste heat and convert it to electrical energy. In an embodiment, thermoelectric device 2600 may include a pathway 2602 along which heat from a heat source can be directed, an array of thermoelectric elements 2604 for converting heat from the pathway 2602 into electrical energy, and a dissipating member 2606 that can dissipate heat from the thermoelectric elements 2604 to create a temperature differential across the elements 2604 in order to enhance the conversion of heat into electrical energy. In an embodiment, pathway 2602 and dissipating member 2604 may be made from a nanotube-based material so as to reduce the weight of thermoelectric device 2600 and enhance heat transfer. The thermoelectric elements 2604 may also be made from a nanotube-based material to reduce weight and enhance generation of electrical power. However, any material having thermoelectric properties can be used. These elements and features of thermoelectric device 2600 will be discussed below in additional detail.

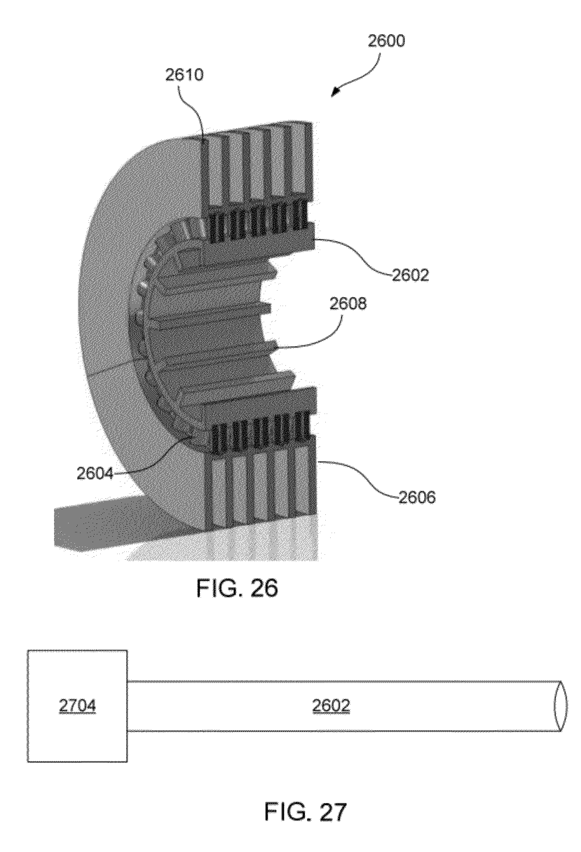

An example of a pathway 2602 is shown in FIG. 27. Pathway 2602 may be made from a heat conductive material so that heat from source 2704 can be directed along pathway 2602. In an embodiment, pathway 2602 may have a solid body so that it can conduct heat through its body. In another embodiment, pathway 2602 can be hollow pipe or hose so that a heated fluid can be directed through pathway 2602. For example, pathway 2602 can be an exhaust pipe for expelling heated exhaust gas, a hose that carries coolant from an engine after the engine has heated the coolant, etc.

In an embodiment, if pathway 2602 is a hollow tube, pipe, or hose, pathway 2602 can include extensions 2608 (as shown in FIG. 26) that extend or project into a flow of heated fluid so as to enhance heat transfer from the heated fluid to thermoelectric elements 2604. The extensions 2608 can, for example, increase the interior surface area of the pipe to facilitate heat transfer from a heated exhaust gas flowing through the pipe to thermoelectric element 2604. In an embodiment, these extensions 2608 can be fins that are arranged along the length of pathway 2602, as shown in FIG. 26, so that the flow of fluid is substantially parallel to the extensions 2608. In another embodiment, extensions 2608 can be arranged transversely, or at an angle to the flow of fluid if desired. Extensions 2608 can also be spikes, blades, fins, or other structures that can extend into the flow of fluid to facilitate heat transfer. In an embodiment, the extensions 2608 can extend from an interior surface of pathway 2602, can be coupled to a surface of pathway 2602, or can extend through pathway 2602. For example, extensions 2608 can extend through the body of pathway 2602 so that one side or end of the extension 2608 is in thermal contact with the heated fluid, while another side or end of the extension 2608 is in thermal contact with thermoelectric elements 2604, dissipating member 2606, and/or the ambient environment surrounding thermoelectric device 2600.

Although shown as a cylindrical pathway, pathway 2602 can have any desired shape (e.g. square, rectangular, etc.) so long as pathway 2602 can receive heat from source 2704. Also, although shown as a straight pathway, pathway 2602 can be curved or angled as desired.

In order to conduct heat and reduce the weight of thermoelectric device 2600, pathway 2602 can be made from a carbon nanotube material (such as a carbon nanotube material described above). The carbon nanotube material may be light weight, so the weight of thermoelectric device 2600 can be reduced while thermal performance of pathway 2602 is enhanced. In an embodiment, pathway 2602 can be made from a composite material that includes carbon nanotubes. The carbon nanotubes in the composite can act to reduce the weight of thermoelectric device 2600 while enhancing heat transfer through pathway 2602. Of course, pathway 2602 can also be made from other thermally conductive materials including metal, ceramic, polymer, or from any other material that can conduct heat.

Turning again to FIG. 27, heat source 2704 can be any type of heat source that can direct heat, or a heated fluid, along pathway 2602. In an embodiment, source 2704 can be an electrical or fossil fuel powered heat source. In another embodiment, source 2704 be an engine that produces exhaust gas that can travel through and heat pathway 2602.

In order to convert the heat from pathway 2602 into electrical energy, the thermoelectric device 2600 may include thermoelectric elements 2604 that can be situated along pathway 2602 in an array. In an embodiment, the array of thermoelectric elements 2604 may be situated about an outer surface of pathway 2602. Thermoelectric elements 2604 can be disposed about pathway 2602 in an array so as to increase or enhance the amount of heat that can be transferred from pathway 2602 to thermoelectric elements 2604. Although shown as an array, thermoelectric element 2604 can also be situated about pathway 2602 in any manner that allows heat to transfer from pathway 2602 to thermoelectric element 2604. In addition, the array in which the thermoelectric elements 2604 are arranged can be an ordered or non-ordered array.

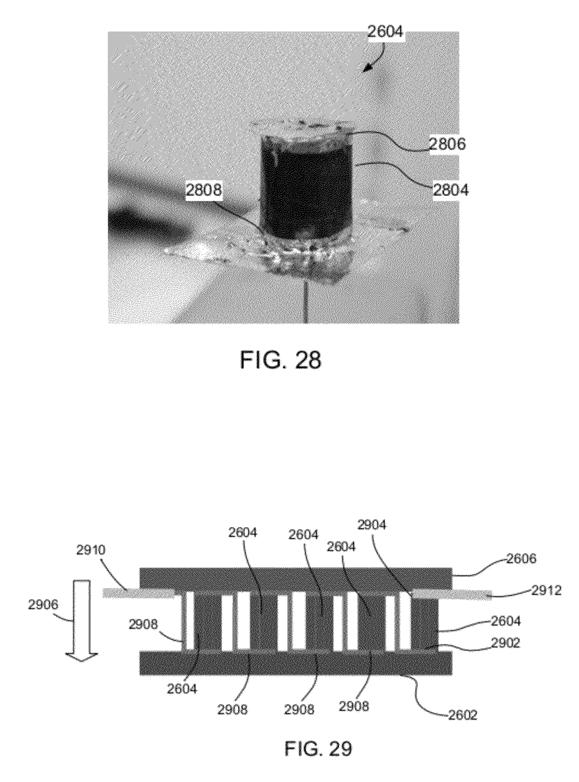

FIG. 28 shows one embodiment of a thermoelectric element 2604 of the present invention. As shown, thermoelectric element 2604 may include thermoelectric material 2804, that can convert heat to electrical energy. To increase thermoelectric efficiency, thermoelectric material 2804 may be arranged to maximize the mass of thermoelectric material within thermoelectric element 2604. Accordingly, thermoelectric material 2804 may be a sheet or strip of thermoelectric material that has been rolled into a cylinder or scroll. In another embodiment, thermoelectric material 2804 may be a solid piece of thermoelectric material. In yet another embodiment, thermoelectric material 2804 can be arranged in any shape to facilitate electrical energy generation. For example, thermoelectric material 2804 can be formed into a rectangular prism or a cube shape. In this embodiment, thermoelectric elements 2604 can be tightly arranged in the array so as to minimize or reduce empty space between the thermoelectric elements 2604 and increase the thermoelectric mass within the array.

In an embodiment, the thermoelectric material 2804 may have a power output of about 1 Watt/gram to about 3 Watts/gram at a temperature of 400 degrees C. Accordingly, increasing the mass of thermoelectric material situated about pathway 2602 can enhance the power output of thermoelectric device 2600. Thermoelectric material 2804 can be any type of thermoelectric material that exhibits the Seebeck effect and/or the Peltier effect for converting heat to electrical energy, or vice versa. For example, thermoelectric material 2804 can be a single nanotube sheet that has been doped with a p-type dopant. In an embodiment, the p-doped sheet can be been rolled into a coil or scroll formation to maximize the amount of thermoelectric mass within thermoelectric element 2604. Thermoelectric material 2804 can also be a single nanotube sheet doped with an n-type dopant, if desired. In another embodiment, thermoelectric material 2804 can include multiple sheets sharing a same doping type that are coupled together in series, or layered upon each other to form a multiple layers. In an embodiment, all the thermoelectric material 2804 within a thermoelectric element 2604 may have a single doping type. To the extent desired, however, the thermoelectric material 2804 can include some material that is p-doped, and some material that is n-doped. For example, thermoelectric material 2804 can be a single sheet with an alternating doping pattern, as described above and shown in FIG. 7, or it can be multiple sheets with alternating doping patterns, as described above and shown in FIG. 14. In another embodiment, thermoelectric material 2804 can be a metal, cement, silicon-based material, semiconductor material, alloy, polymer, crystal, superconductor, or any other material with a desired Seebeck coefficient for converting the heat from pathway 2602 to electrical energy. In an embodiment, the thermoelectric material can have a transition temperature of up to about 600 degrees C. or higher.

Thermoelectric element 2604 may be capped at its ends with a material that can conduct heat and electricity. As shown in FIG. 28, contact pads 2806 and 2808 may be provided at opposing ends of thermoelectric material 2804. The contact pads 2806 and 2808, as provided, can serve as thermal and electrical contacts for thermoelectric element 2604. In an embodiment, the contact pads 2806 and 2808 can be made of a metal that can act as an electrical and thermal conductor, such as nickel or copper. In another embodiment, the contact pads 2806 and 2808 can be made from a nanotube-based material that can conduct heat and electrical current. In general, contact pads 2806 and 2808 can be made of any suitable material for conducting heat and electricity.

Referring again to FIG. 26, thermoelectric device 2600 may also include a dissipating member 2606 adjacent to the array of thermoelectric elements 2604. In an embodiment, dissipating member 2606 may be thermally coupled to one or more of the thermoelectric elements 2604 in the array, so that it can dissipate heat from the array. By dissipating heat, dissipating member 2606 can act to create a heat differential between dissipating member 2606 and pathway 2602, and across thermoelectric elements 2604. Such a heat differential can enable thermoelectric elements 2604 to generate electrical energy. In another embodiment, thermoelectric device 2600 may include multiple dissipating members 2606 coupled to thermoelectric elements 2604 for dissipating heat.

As shown in the embodiment of FIG. 26, dissipating member 2606 can be an air cooled heat sink so that it can dissipate heat from pathway 2602 into the air. For example, if pathway 2602 is an exhaust pipe on an automobile or other vehicle, dissipating member 2606 may be able to dissipate the heat from pathway 2602 into the ambient air. Of course, dissipating member 2606 can be liquid-cooled, fluid-cooled, fan-cooled, or cooled in other ways so long as it can dissipate heat.

In an embodiment, dissipating member 2606 may have a substantially tubular shape so that it can be positioned circumferentially about pathway 2602 and thermal elements 2604. In other embodiments, dissipating member 2606 may have any shape or geometry conducive to dissipating heat or that approximates the profile of the pathway 2602. For example, dissipating member 2606 can be a plate, a tube, a rectangle, or any other shape that can be thermally coupled to thermoelectric elements 2604 and dissipate heat from thermoelectric elements 2604.

Dissipating member 2606 can also have features to increase its surface area, so as to allow for more efficient conductive and convective heat dissipation. For example, dissipating member 2606 may have extensions 2610 that increase a surface area of dissipating member 2606. Extensions 2610 may extend from a surface of dissipating member 2606, may be coupled to a surface of dissipating member 2606, may extend through a surface of dissipating member 2606, etc. Extensions 2610 can be fins, spikes, blades, or any other features that facilitate heat dissipation. As shown in FIG. 26, extensions 2610 may be fins that are arranged substantially perpendicularly to pathway 2602. In another embodiment, extensions 2610 can be arranged along the length of dissipating member 2606 so they are in linear alignment with pathway 2602. Dissipating member 2606 can also include other features that can facilitate heat dissipation, such as pipes that can pass adjacent to or through the body of dissipating member 2606 to provide active or passive fluid cooling, heat pipes containing a heat transfer liquid or a phase change liquid, etc.

Dissipating member 2606 can be made from any material that can act as a thermal conductor. In an embodiment, dissipating member 2606, may be made of a thermally conductive, nanotube-based material to reduce weight of thermoelectric device 2600 while providing sufficient thermal dissipation. Dissipating member may, for example, be made from a composite material that includes nanotubes. The nanotubes within the composite may act to reduce the weight of the composite while enhancing thermal conductivity. In other embodiments, dissipating member 2606 can be made from a metal, a ceramic, a polymer, or a combination of materials.

Pathway 2602, thermoelectric elements 2604, and dissipating member 2606 may be arranged in thermal communication with one another, so that heat can transfer through thermoelectric elements 2604 to allow them to produce electrical energy. FIG. 29 shows an example of how pathway 2602, a plurality of thermoelectric elements 2604, and dissipating member 2606 may be thermally connected. The plurality of thermoelectric elements 2604 in FIG. 29 may, in an embodiment, be an array of the thermoelectric elements 2604 as shown in FIG. 28. As shown, one end 2902 of thermoelectric element 2604 may be soldered, brazed, or otherwise thermally coupled to pathway 2602, so that heat can be conducted from pathway 2602 through thermoelectric element 2604. The opposing end 2904 of thermoelectric element 2604 may be thermally coupled to heat dissipating element 2606, so that heat can flow from thermoelectric element 2604 to dissipating element 2606 for dissipation. When pathway 2602 is heated and/or when dissipating member 2606 is cooled, it can act to create a heat differential, from pathway 2602 to dissipating member 2606, across the thermoelectric elements 2604 in the direction shown by arrow 2906. This heat differential can allow thermoelectric elements 2604 to generate electrical energy.

So that the electrical energy can be harvested and used, thermoelectric elements 2604 may be electrically connected by electrical conductors 2908. As shown, electrical conductors 2908 may connect thermoelectric elements 2604 in series. This can allow the connected series of thermoelectric elements 2604 to produce a larger voltage than a single thermoelectric element. Thermoelectric elements 2604 can also be connected in parallel (not shown). Connecting thermoelectric elements 2604 in parallel can allow the connected thermoelectric elements to produce a larger current than a single thermoelectric element. Series connections, parallel connections, or a combination thereof can be used within the array of thermoelectric elements 2604 to produce a desired current and voltage output of the array. Additionally, electrical connectors 2910 and 2912 can be coupled to one or more thermoelectric elements 2604 so that the electrical energy generated by thermoelectric elements 2604 can be used. Furthermore, the output power may be increased by increasing the number of thermoelectric elements 2604 in the array situated about pathway 2602.

In an embodiment, an electrical insulator may be placed between the thermoelectric elements 2604 and pathway 2602 so that any flow of electrical current between the thermoelectric elements 2604 and the pathway 2602 can be reduced or minimized. Similarly, an electrical insulator may be placed between thermoelectric elements 2604 and dissipating member 2606 so that any flow of current between thermoelectric elements 2604 and dissipating member 2606 can be reduced or minimized. The electrical insulators, in an embodiment, can also be thermally conductive so that heat can continue to flow from pathway 2602, through thermoelectric elements 2604, to dissipating member 2606.

### Example of Operation

In an embodiment, the thermoelectric device 2600 can be used to harvest waste heat from engine exhaust. In this example, pathway 2602 may be an exhaust pipe. In an embodiment, the exhaust pipe may have a diameter of about three inches. However, exhaust pipes of any other diameter can be used. An engine can expel exhaust gas through the exhaust pipe so that the exhaust pipe becomes heated by the gas. In one embodiment, the exhaust gas may be heated by the engine to about 350 degrees C.

An array of thermoelectric elements may be situated in an array along the length of the exhaust pipe. The array may, for example, cover about a six-inch length of the pipe. A dissipating heat sink may be coupled to the array so that heat from the exhaust pipe can flow through the thermoelectric elements to the to heat sink, and subsequently dissipate into the ambient air. The difference in temperature between the heat sink and the exhaust pipe can form a temperature differential across the thermoelectric elements, which can drive the thermoelectric elements to produce electrical energy. In an embodiment, and depending upon the amount of thermoelectric material in the array and the ambient air temperature, such an array of thermoelectric elements situated about a six-inch length of a three-inch diameter exhaust pipe can produce up to about 50 Watts of electrical power or more.

Although discussed in connection with dissipating heat, thermoelectric device 2600 can be used to generate electrical energy from heat flowing into pathway 2602 from member 2606. For example, in an embodiment, a cold fluid or coolant may be directed through pathway 2602. In this case, pathway 2602 may be cooled to a temperature that is relatively cooler than member 2606. This may allow heat to flow from member 2606, through thermoelectric elements 2604, and into pathway 2602. Accordingly, this may create a heat differential across thermoelectric elements 2604 in a direction opposite to the direction of arrow 2906 in FIG. 29. This heat differential may allow thermoelectric elements 2604 to generate electrical energy.

### APPLICATIONS

The thermoelectric device of the present can be utilized for a number of other applications. Among these, devices can be manufactured for applications including: A solar battery charger; a high energy, light weight transient thermal battery replacement placed in rockets or missiles; a low temperature energy harvester suitable for substrate heat battery charging or applications used at very low temperatures, such as sub-zero (i.e., below 0° C.) or temperatures in space or in Arctic or Antarctic environments; a 1 Mega-Watt thermal generator; and a waste heat energy harvester such as a thermoelectric generator situated to collect heat energy from an exhaust pipe and convert it into electrical energy.

Light weight thermoelectric devices can also be manufactured in combination with solar cells to capture the waste heat radiated to space. These devices can be designed to heat pathway 2602 to a temperature of about 370 degrees K and dissipate heat from dissipating member 2606 to about a 50 degrees K. This very large temperature differential can enable the capture of significant amounts of new power and allow the solar arrays to operate at a reduced temperature thereby improving their efficiency.

Carbon nanotube thermoelectric devices of the present invention can further be used in conjunction with waste heat from satellites, communication electronics, and power systems, for power harvesting and thermal management purposes. An example may be a substrate heat powered device used for charging batteries. In particular, carbon nanotube thermoelectric blanket power sources could replace delicate, heavy, and expensive GaAs cells and coated cover glass components in photovoltaic arrays, so as to eliminate the costly multi-step assembly. This in turn would permit improved on-station altitude control and reduced propellant usage for either lower launch costs or extended mission operations. Future civil and defense spacecraft may also need more efficient, higher power sources and improved thermal management systems in order to meet escalating mission performance goals. As such, the thermoelectric devices of the present invention can be used for such purposes

Another example may be to use the thermoelectric devices of the present invention in conjunction with various machines, electronic devices, or power systems that generate waste heat. The present invention contemplates using the thermoelectric devices to harvest the waste heat, convert the waste heat to electrical power, and redirecting the power to these machines, devices or systems for reuse, so as to enhance efficiency and reduce overall power usage.

While the present invention has been described with reference to certain embodiments thereof, it should be understood by those skilled in the art that various changes may be made and equivalents may be substituted without departing from the true spirit and scope of the invention. In addition, many modifications may be made to adapt to a particular situation, indication, material and composition of matter, process step or steps, without departing from the spirit and scope of the present invention. All such modifications are intended to be within the scope of the claims.

What is claimed is:

1. A thermoelectric system comprising:
a carbon nanotube-based pathway along which heat from a source can be directed;
an array of thermoelectric elements for generating electrical energy situated about a surface of the pathway and in thermal communication with the pathway to permit the generation of electrical energy; and
a carbon nanotube-based dissipating member in thermal communication with the array of thermoelectric elements and operative to create a heat differential between the thermoelectric elements and the pathway by dissipating heat from the thermoelectric elements, so as to allow the thermoelectric elements to generate the electrical energy.

2. A system as set forth in claim 1, wherein the pathway is a tubular pathway through which a heated fluid can flow.

3. A system as set forth in claim 2, further comprising extensions projecting into the flow of heated fluid to enhance the transfer of heat to the thermoelectric elements.

4. A system as set forth in claim 1, wherein the pathway includes thermally conductive, nanotube-based material to reduce the weight of the pathway while allowing heat transfer.

5. A system as set forth in claim 1, wherein each thermoelectric element includes a carbon nanotube-based sheet.

6. A system as set forth in claim 1, wherein each thermoelectric element is formed from a sheet of thermoelectric material that is rolled into a cylinder.

7. A system as set forth in claim 1, wherein each thermoelectric element includes a thermal contact on one end, to couple the thermoelectric element to the pathway, and a thermal contact on an opposing end, to couple the thermoelectric element to the dissipating member, so as to facilitate heat flow from the pathway to the dissipating member through the thermoelectric elements.

8. A system as set forth in claim 1, wherein the thermoelectric elements in the array are electrically connected to enhance generation of electrical power.

9. A system as set forth in claim 8, wherein the thermoelectric elements are connected in series, in parallel, or in a combination thereof.

10. A system as set forth in claim 1, wherein the thermoelectric elements are arranged in an ordered pattern to enhance the flow of heat through the thermoelectric elements, and enhance the electrical energy generated by the thermoelectric elements.

11. A system as set forth in claim 1, wherein the dissipating member is positioned about the array of thermoelectric elements, so that the heat can be transferred radially from the pathway, through the thermoelectric elements, to the heat conductive member.

12. A system as set forth in claim 1, wherein the dissipating member includes extensions that project away from the pathway to enhance heat dissipation.

13. A system as set forth in claim 1, wherein the dissipating member includes a thermally conductive, nanotube-based material to reduce the weight of the dissipating member while allowing heat to dissipate from the dissipating member.

14. A method of converting heat to electrical energy, the method comprising:
transferring heat from a pathway into an array of thermoelectric elements arranged in a pattern about a pathway and in thermal communication with the pathway to permit generation of electrical energy;
using a dissipating member made from a carbon nanotube based material, in thermal communication with the thermoelectric elements, to dissipate the heat from the thermoelectric elements, so as to create a heat differential between the thermoelectric elements and the pathway; and
allowing the thermoelectric elements, in the presence of the heat differential, to generate the electrical energy.

15. A method as set forth in claim 14, wherein, in the step of transferring, the pathway is a pipe or hose.

16. A method as set forth in claim 14, wherein the step of transferring includes directing a heated fluid through the pipe or hose in order to heat the pipe or hose.

17. A method as set forth in claim 14, wherein the step of using includes dissipating the heat into an ambient environment.

18. A method as set forth in claim 14, further comprising using the thermoelectric elements as an electrical power source.
